(19) United States
(12) Patent Application Publication
(10) Pub. No.: US 2013/0009305 A1
(43) Pub. Date: Jan. 10, 2013

(54) SEMICONDUCTOR DEVICE AND METHOD OF MANUFACTURING THE SAME

(75) Inventor: Daisuke OSHIDA, Kanagawa (JP)

(73) Assignee: Renesas Electronics Corporation

(21) Appl. No.: 13/538,353

(22) Filed: Jun. 29, 2012

(30) Foreign Application Priority Data
Jul. 7, 2011 (JP) 2011-150612

(51) Int. Cl. H01L 23/528; H01L 21/768

(52) U.S. Cl. 257/737; 257/774; 438/637; 438/613; 257/E23.151; 257/E21.577

(57) ABSTRACT

A semiconductor device having a first via and a first interconnect supplying a high current is provided in which a first surface having the first via and the first interconnect is planar. The semiconductor device has a first via penetrating a first substrate from a first surface of the first substrate and a first interconnect buried in the first surface of the first substrate and connected with one end of at least one first via. The first via has an inclined portion where an angle formed between a lateral side of the first via and the bottom of the first via is larger than an angle formed between a lateral side of the first interconnect and the bottom of the first interconnect.

### CROSS-REFERENCE TO RELATED APPLICATION

The disclosure of Japanese Patent Application No. 2011-150612 filed on Jul. 7, 2011 including the specification, drawings and abstract is incorporated herein by reference in its entirety.

### BACKGROUND

The present invention relates to a semiconductor device and a method of manufacturing the same.

Along with increase in the integration degree of semiconductor devices, various multi-layered interconnection structures have been proposed.

Japanese Unexamined Patent Publication No. 2010-045371 describes the following through silicon via (TSV) structure. A conductive via in the TSV structure is extended from the upper surface to the lower surface of a substrate and penetrates the substrate. Further, a conductive protective film comprising at least one of Ni and Co is formed at the bottom of the conductive via. Further, a separation polymer insulating film is formed to the lower surface of the substrate while being in contact with the conductive protective film. It is described that a TSV structure capable of suppressing strain of a semiconductor substrate can be proposed.

Further, Japanese Unexamined Patent Publication No. 2010-080897 describes the following semiconductor device. A first semiconductor chip and a second semiconductor chip are bonded to each other. An electrode pad is formed at the surface portion of the first semiconductor chip. A through via is formed in the second semiconductor chip. An engraved portion is formed in the electrode pad and the bottom of the through via is buried in the engraved portion. It is described that the bonding strength between the through via and the electrode pad can be increased thereby increasing the mechanical strength of the semiconductor device having a three-dimensional interconnect structure.

Further, Japanese Unexamined Patent Publication No. 2009-302453 (Patent Document 3) describes the following semiconductor device. A concave portion is formed to the rear face of a semiconductor chip. A rear face interconnect pad as a portion of the through silicon via and a rear face interconnect are formed in the inside of the concave portion. It is described that planarity of the rear face of the chip can be ensured to suppress lowering of adsorption force when handling of the chip.

Further, Japanese Unexamined Patent Publication No. 2009-277927 describes the following circuit substrate. A circuit pattern is disposed to one surface of a substrate. A through silicon via is filled inside a through hole formed in the substrate and joined at one end to a circuit pattern. The circuit pattern and the through silicon via have regions containing a noble metal ingredient respectively and are joined to each other by way of the regions. It is described that this can suppress the generation of an oxide film on the surface of the circuit pattern and generation of voids in the through hole. The Japanese Unexamined Patent Publication No. 2009-277927 describes, in FIG. 1, a through via having a depth-to-bottom aspect ratio of 1 or greater.

Further, Japanese Unexamined Patent Publication No. 2009-010312 describes the following stacked package. First and second semiconductor chips are disposed such that bonding pad forming surfaces are opposed each other. A plurality of TSVs are formed in the first and second semiconductor chips. A plurality of interconnects are formed on the bonding pad forming surfaces of the first and second semiconductor chips so as to connect the TSV and the bonding pads. It is described that strain and cracking of the wafer and the semiconductor chip generated in the course of manufacture can be suppressed.

Further, Japanese Unexamined Patent Publication No. 2009-004722 describes a method of manufacturing a semiconductor package including a step of removing the lower surface of a semiconductor chip such that the bottom of a through silicon via protrudes from the semiconductor chip. It is described that the manufacturing step of a stacked type semiconductor package can be simplified thereby decreasing the manufacturing cost.

Further, Japanese Unexamined Patent Publication No. Hei 08 (1996)-255797 describes a method of manufacturing a semiconductor substrate as described below. At first, a trench is formed in one main surface of a first silicon substrate. Then, a metal layer is formed in the inside of the trench. Then, at least a portion of the metal layer is silicided by a heat treatment. Then, the one main surface is planarized. Then, the one main surface of the first silicon substrate and a second silicon substrate are joined. It is described that a semiconductor device having a buried layer of silicide at a low resistance in the substrate and with fewer defects can be provided at low cost.

### SUMMARY

In Japanese Unexamined Patent Publication No. 2010-045371 to Japanese Unexamined Patent Publication No. Hei 08 (1996)-255797 described above, no investigation is made on the method of forming via holes and interconnect trenches and then burying a metal simultaneously in the via holes and the interconnect trenches by a plating method.

In the step of burying a metal after forming via holes and interconnect trenches, the present inventors have found that the following subject is caused when a metal is buried in the via holes and the interconnect trenches simultaneously by a plating method. While the via hole has a high aspect ratio, the interconnect trench is shallow and has a low aspect ratio. Therefore, when the metal is buried simultaneously by a plating method, the metal is buried previously in the interconnect trench than in the via hole, and the metal on the interconnect trench is filled in a raised shape. As described above, since the surface of the substrate in which the metal is buried lacks in planarity, there has been found a problem that uniform polishing is impossible in a CMP (chemical mechanical polishing) step.

The present invention provides, in a first aspect, a semiconductor device including: a first substrate, a first via penetrating the first substrate from a first surface of the first substrate, and a first interconnect buried in the first surface of the first substrate and connected with one end of at least one first via, in which the first via has an inclined portion where an angle formed between the lateral side of the first via and the bottom of the first via is larger than an angle formed between the lateral side of the first interconnect and the bottom of the first interconnect.

The present invention provides, in a second aspect, a semiconductor device including: a first substrate, a first interlayer insulating film disposed over a first surface of the first substrate, a first interlayer via penetrating the first interlayer insulating film, and a first interconnect buried in a surface of the first interlayer insulating film and connected with one end of at least one first interlayer via, in which the first interlayer via has an inclined portion where an angle formed between the lateral side of the first interlayer via and the bottom of the first interlayer via is larger than an angle formed between the lateral side of the first interconnect and the bottom of the first interconnect.

The present invention provides, in a third aspect, a method of manufacturing a semiconductor device including: an etching step of forming a first via hole penetrating a first substrate from a first surface of a first substrate and forming a first interconnect trench connected with one end of at least one first via hole, and a metal burying step of burying a metal in the first via hole and the first interconnect trench, thereby forming a first via and a first interconnect, in which an inclined portion is formed in the first via hole where an angle formed between the lateral side and the bottom is larger than an angle formed between the lateral side of the first interconnect trench and the bottom of the first interconnect trench in the etching step.

The present invention provides, in a fourth aspect, a method of manufacturing a semiconductor device including: a step of forming a first interlayer insulating film over a first surface of a first substrate, an etching step of forming a first interlayer via hole penetrating the first interlayer insulating film and forming a first interconnect trench connected with one end of at least one first interlayer via hole, and a metal burying step of burying a metal in the first interlayer via hole and the first interconnect trench, thereby forming the first interlayer via and the first interconnect, in which an inclined portion is formed in the first interlayer via hole where an angle formed between the lateral side and the bottom is larger than an angle formed between the lateral side of the first interconnect trench and the bottom of the first interconnect trench in the etching step.

According to the invention, the first via (first interlayer via) has an inclined portion where the angle formed between the lateral side and the bottom of the first via (first interlayer via) is larger than the angle formed between the lateral side and the bottom of the first interconnect. Thus, the metal burying rate in the first via hole can be increased more than that in the first interconnect trench in the subsequent metal burying step. Then, the first surface of the first substrate after burying the metal can be planarized and, further, planarized uniformly in CMP. Accordingly, it is possible to provide a semiconductor device which has a first via (first interlayer via) and a first interconnect for supplying a high current and in which the first surface formed with the first via (first interlayer via) and the first interconnect is planar.

The present invention can provide a semiconductor device having a first via and a first interconnect for supplying a high current in which the first surface formed with the first via and the first interconnect is planar.

### DESCRIPTION OF THE ACCOMPANYING DRAWINGS

FIG. 1 is a cross sectional view showing a configuration of a semiconductor device according to a first embodiment, in which

FIG. 1A is a cross sectional view along line A-A′ in FIG. 2 to be described later,

FIG. 1B is a cross sectional view along line B-B′ in FIG. 2A, and

FIG. 1C is a cross sectional view along line C-C′ in FIG. 1A;

FIG. 2 is a plan view showing a configuration of a semiconductor device according to the first embodiment;

FIG. 3 is an enlarged cross sectional view of the semiconductor device in FIG. 1A;

FIG. 4 is a graph showing a relation of an angle formed between the lateral side and the bottom in a first via or in a first interconnect to a metal burying rate;

FIG. 5 is an enlarged cross sectional view of a first via in FIG. 1B;

FIG. 6 is a view for explaining the effect of the first embodiment, in which

FIG. 6A is a view showing a step of preparing a first substrate and

FIG. 6B is a view showing a step of forming a first via hole;

FIG. 7 is a cross sectional view for explaining a method of manufacturing the semiconductor device according to the first embodiment in which

FIG. 7A is a view showing a step of preparing a resist film and

FIG. 7B is a view showing a step succeeding to FIG. 7A;

FIG. 8 is a cross sectional view for explaining the method of manufacturing the semiconductor device according to the first embodiment in which

FIG. 8A is a view showing a step of forming a first via hole and a first interconnect trench,

FIG. 8B is a view along line B-B in FIG. 8A, and

FIG. 8C is a view along line C-C in FIG. 8A;

FIG. 9 is a cross sectional view for explaining the method of manufacturing the semiconductor device according to the first embodiment in which

FIG. 9A is a view showing a step of forming a liner insulating film, and

FIG. 9B is a view showing a step of forming a barrier metal layer;

FIG. 10 is a cross sectional view for explaining the method of manufacturing the semiconductor device according to the first embodiment in which

FIG. 10A is a view showing a step of burying a metal, and

FIG. 10B is a view showing a step of forming a first bump electrode;

FIG. 11 is a cross sectional view showing a configuration of a semiconductor device according to a second embodiment;

FIG. 12 is a cross sectional view showing a configuration of a semiconductor device according to a third embodiment;

FIG. 13 is a cross sectional view showing a configuration of a semiconductor device according to a fourth embodiment;

FIG. 14 is a cross sectional view showing a configuration of a semiconductor device according to a fifth embodiment;

FIG. 15 is a cross sectional view showing a configuration of a semiconductor device according to a sixth embodiment;

FIG. 16 is a cross sectional view showing a configuration of a semiconductor device according to a seventh embodiment;

FIG. 17 is s a cross sectional view showing a configuration of a semiconductor device according to an eighth embodiment; and

FIG. 18 is a cross sectional view showing a configuration of a semiconductor device according to a ninth embodiment.

### PREFERRED EMBODIMENTS OF THE INVENTION

Preferred embodiments of the invention are to be described with reference to the drawings. Through out the drawings, identical constituent elements carry the same reference numerals for which descriptions are sometimes omitted.

### First Embodiment

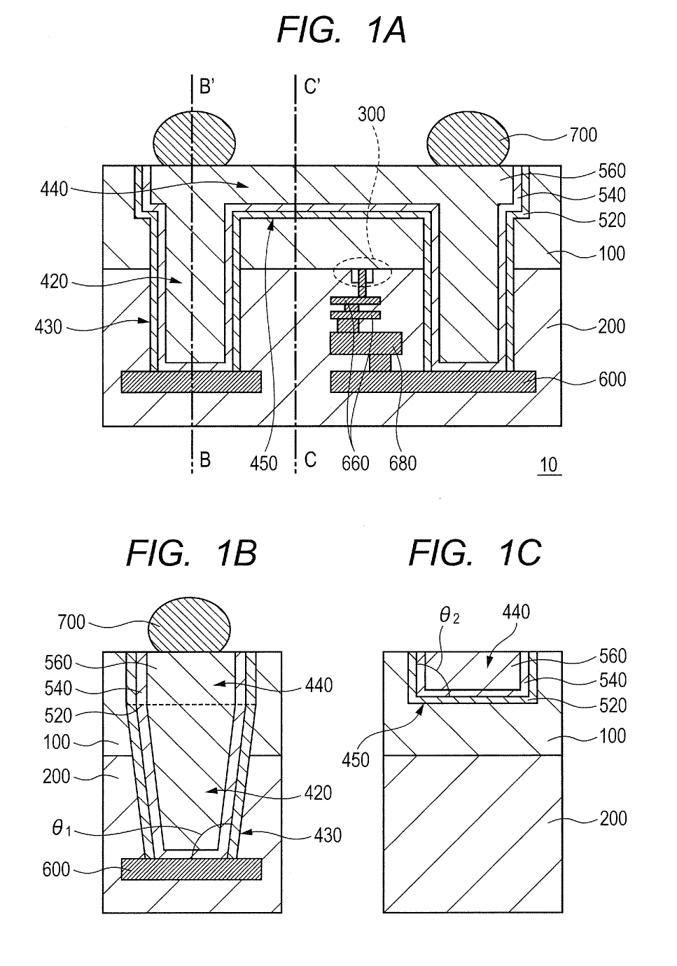

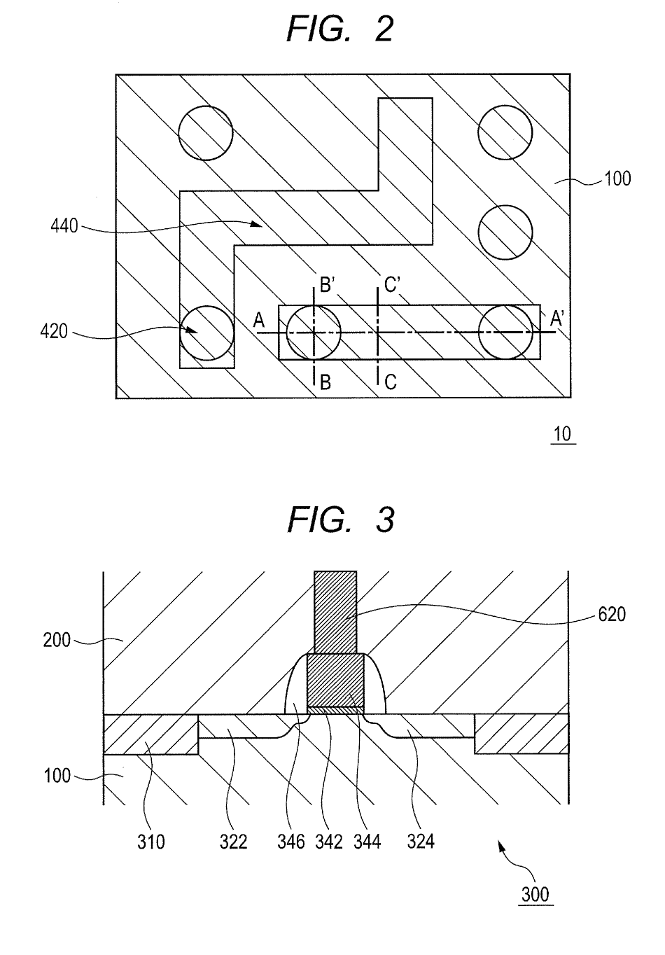

A semiconductor device 10 according to the first embodiment is to be described with reference to FIG. 1 to FIG. 5. At first, FIG. 1 is a view showing a configuration of the semiconductor device 10 according to the first embodiment. FIG. 1A is a cross sectional view along line A-A′ in FIG. 2 to be described later. FIG. 1B is a cross sectional view along line B-B′ in FIG. 1A. FIG. 1C is a cross sectional view along line C-C′ in FIG. 1A. The semiconductor device 10 has the following configuration. The semiconductor device 10 has a first substrate 100, first vias 420 penetrating the first substrate 100 from the side of first surface of the first substrate 100, a first interconnect 440 buried in a first surface of the first substrate 100 and connected with one end of at least one of the first vias 420. Further, the first via 420 has an inclined portion where an angle θ₁ formed between the lateral side of the first via 420 and the bottom of the first via 420 is larger than an angle θ₂ formed between the lateral side of the first interconnect 440 and the bottom of the first interconnect 440. Description is to be made more specifically.

As shown in FIG. 1A, the first via 420 penetrating the first substrate 100 from the first surface of the first substrate 100 is formed. The first substrate 100 is, for example, a silicon substrate.

The “first via 420” means an interconnect hole including a barrier metal layer 540 to be described later and a metal 560 buried in the barrier metal layer 540 by plating. “First via 420” does not include a liner insulating film 520.

Further, the first interconnect 440 is buried in the first surface of the first substrate 100 and connected with one end of at least one of the first vias 420.

“First interconnect 440” referred to herein means an interconnect including the barrier metal layer 540 to be described later and the metal 560 buried inside the barrier metal layer 540 by plating. “First interconnect 440” does not include the liner insulating film 520.

The first interconnect 440 is, for example, an interconnect for flowing a high current supplied from a printed wiring board (not illustrated), etc. when the semiconductor device 10 is mounted over the printed wiring board (not illustrated), etc. Further, the first interconnect 440 supplies a current by way of the first via 420 to a power supply interconnect such as a second interconnect 600 to be described later or a ground interconnect.

The height (depth) of the first interconnect 440 is 5 μm or more and 100 μm or less, and can supply a high current to the first interconnect 440.

The first via 420 and the first interconnect 440 are formed by burying the metal 560 in the first via hole 430 and the first interconnect trench 450 formed in the first substrate 100. In FIG. 1, a first via hole 430 is shown as being formed at the boundary between the liner insulating film 520 and the first substrate 100 in the manufacturing step. Further, a first interconnect trench 450 is shown also as being formed at the boundary between the liner insulating film 520 and the first substrate 100 in the manufacturing step. The manufacturing method including the metal burying step is to be described specifically later.

The liner insulating film 520 is formed on the lateral side of the first via hole 430 and the lateral side and the bottom of the first interconnect trench 450. That is, the liner insulating film 520 is formed so as to be in contact with the lateral side of the first via 420 and the bottom and the lateral side of the first interconnect 440 except the bottom of the first 420 of the first via 420 and the first interconnect 440. The liner insulating film 520 is a film, for example, formed of one of SiO₂, SiN, SiCN, SiON, and SiC, or a stacked film comprising them. Further, the thickness of the liner insulating film 520 is, for example, 20 nm or more and 200 nm or less.

Further, a barrier metal layer 540 is formed on the lateral side and the bottom inside the first via 420 and the first interconnect 440. The barrier metal layer 540 is formed, for example, of Ta, TaN, Ti, TiN, Mn, CoWP, Co, NiB, W, or Al. The thickness of the barrier metal layer 540 is, for example, 20 nm or more and 250 nm or less.

Further, the metal 560 is buried inside the barrier metal layer 540 by a plating method. The metal 560 includes, for example, Cu, Al, W, Ti, TiN, Ta, TaN, Mn, or Co, or an alloy of such metals.

As described above, the barrier metal layer 540 is not formed at the boundary between the first via 420 and the first interconnect 440, and the metal 560 is formed continuously in the first via 420 and the first interconnect 440.

Further, a first bump electrode 700 connected with the first via 420 or the first interconnect 440 is disposed over the first interconnect 440 of the first substrate 100. The first bump electrode 700 is formed, for example, just above the first via 420. The material of the first bump electrode 700 comprises, for example, Sn, Sn—Ag, Sn—Ag—Cu, Au, etc. Thus, the first substrate 100 can be mounted by way of the first bump electrode 700 of the first surface to the printed wiring board, etc.

The first substrate 100 has a second interconnect 600 over a second surface opposing the first surface formed with the first interconnect 440, etc. Further, the other end of the first via 420 is connected with the second interconnect 600. The second interconnect 600 is not particularly restricted so long as this is an interconnect formed over the second surface of the first substrate 100. In FIG. 1, the second interconnect 600 is an interconnect formed in the first interlayer insulating film 200. Alternatively, the second interconnect 600 may also be an interconnect (not illustrated) formed so as to be in contact just over the second surface of the first substrate 100 not by way of a first interlayer insulating film 200, etc. Thus, a current can be supplied from the first surface of the first substrate 100 to the second interconnect 600, etc.

In the first embodiment, a semiconductor device 300 is formed on the side of the second surface opposing the first surface of the first substrate 100. The semiconductor device 300 is to be described later specifically.

In the first embodiment, the first interlayer insulating film 200 is disposed over the second surface of the first substrate 100. The first interlayer insulating film 200 may also be a multi-layered structure. The first interlayer insulating film 200 includes, for example, SiO₂, SiN, SiON, SiOC, SiOCH, SiCOH, or SiOF. The second interconnect 600 described above is buried in the uppermost layer of the first interlayer insulating film 200.

Further, a contact connected with the semiconductor device 300 (for example, contact 620 to be described later) and a local interconnect 660 connected by way of the contact 620 to the semiconductor device 300 are formed on the side of the second surface. Further, vias (unnumbered) for connecting the local interconnects 660 to each other, connecting the local interconnect 660 and the local interconnect 680 to each other, and connecting the local interconnect 680 and the second interconnect 600 to each other are formed. The second interconnect 600 is referred to as “global interconnect”.

The first via 420 penetrates the first substrate 100 and also partially penetrates the first interlayer insulating film 200. As described above, the other end of the first via 420 is connected with the second interconnect 600. The first via 420 can be connected with the second interconnect 200 through the first interlayer insulating film 200 where the local interconnect 660 and the local interconnect 680 are formed.

The second interconnect 600 is, for example, a power supply interconnect for supplying a current to the semiconductor device 300, etc. or a ground interconnect disposed in the first substrate 100. As described above, the second interconnect 600 is connected with the other end of the first via 420 and a high current can be supplied.

Further, as shown in FIG. 1B, the first via 420 has an inclined portion (unnumbered). The position for forming the inclined portion in the first via 420 is not restricted. However, the inclined portion is preferably formed at least to a pair of opposing lateral sides in the first via 420. The inclined portion is formed preferably to a portion in contact with the bottom of the first via 420 so that the upper layer of the first via 420 is previously buried earlier so that voids are not formed in the lower layer of the first via 420. In this embodiment the inclined portion is formed for the entire opposing lateral sides of the first via 420 in the direction vertical to the extending direction of the first interconnect 440.

In the inclined portion described above, the angle formed between the lateral side of the first via 420 and the bottom of the first via 420 is larger than the angle formed between the lateral side of the first interconnect 440 and the bottom of the first interconnect 440. In the inclined portion shown in FIG. 1B, the angle formed between the lateral side of the first via 420 and the bottom of the first via 420 assumed as θ₁, and the angle formed between the lateral side of the first interconnect 440 and the bottom of the first interconnect 440 assumed as θ₂ are in a relation: θ₁>θ₂. The angle θ₁ formed between the lateral side and the bottom of the first via 420 corresponds to an angle θ₁ formed between the lateral side and the bottom of the first via hole 430 to be described later. Further, the angle θ₂ formed between the lateral side and the bottom of the first interconnect 440 corresponds to an angle θ₂ formed between the lateral side and the bottom of the first interconnect trench 450 as will be described later. While the respective angles θ₁ and θ₂ are different depending on the thickness of the liner insulating film 520, the effect of the thickness on the angle is slight. Thus, the burying rate of the metal in the first via hole 430 can be increased more than that in the first interconnect trench 450 in the metal burying step to be described later.

Then, a configuration of the semiconductor device 10 in a plan view is to be explained with reference to FIG. 2. FIG. 2 is a plan view showing the configuration of the semiconductor device according to the first embodiment. In the plan view of FIG. 2, as observed on the side of the first surface of the first substrate 100, a first bump electrode 700 is not illustrated.

The first vias 420 are formed each in a circular shape in the plan view. The first via 420 is formed so as to have a bottom in electric connection at the metal 560 with the second interconnect 600, etc. at a portion where the other end of the first via 420 is in contact with the second interconnect 600, etc. That is, it is undesirable that the first via 420 is tapered along the inclined portion and is insulated by the liner insulating film 520 at a portion in contact with the second interconnect 600, etc. Accordingly, the diameter of the first via 420 on the side of the first surface of the first substrate 100 is determined to an optimal size in accordance with the penetrating length of the first via 420. Specifically, the diameter of the first via 420 is, for example, 1 μm or more and 8 μm or less.

Further, the first via 420 may be formed independently without connection at one end to the first interconnect 440. Such a first via 420 is used for direct connection with a printed wiring board (not illustrated), etc.

The first interconnect 440 is, for example, an interconnect for supplying a high current. Accordingly, the first interconnect 440 is formed at larger height and width than those of the local interconnect 660 or the local interconnect 680 which is connected with the semiconductor device 300, etc. Specifically, the height of the first interconnect 440 is 5 μm or 50 μm or less. The width of the first interconnect 440 is larger than the diameter and less than four times the diameter of the first via 420. Specifically, the width is 1 μm or more and 12 μm or less. Thus, a high current can be supplied through the first interconnect 440. On the other hand, when the width of the first interconnect 440 exceeds the upper limit, dishing in the CMP step is not negligible.

Then, the semiconductor device 300 is to be described with reference to FIG. 3. FIG. 3 is an enlarged cross sectional view of the semiconductor device 300 in FIG. 1A. FIG. 3 is turned upside down relative to FIG. 1A.

As shown in FIG. 3, the semiconductor device 300 is, for example, a MOSFET (Metal Oxide Semiconductor Field Effect Transistor). The semiconductor device 300 may also be a resistor, capacitor, inductor, etc. Description is to be made for a case where the semiconductor device 300 is the MOSFET.

As shown in FIG. 3, a device isolation region 310 is formed in the first substrate 100. A source region 322 and a drain region 324 implanted with impurities are formed at the opened portion of the device isolation region 310 near the second surface of the first substrate 100.

A gate insulating film 342 is formed over a channel region (not illustrated) put between the source region 322 and the drain region 324. Further, a gate electrode 344 is formed over the gate insulating film 342. Further, a side wall insulating film 346 is formed on both sides of the gate insulating film 342 and the gate electrode 344.

Further, the gate electrode 344 is connected by way of a contact 620 to a second interconnect 600. While FIG. 3 shows an example where the gate electrode 344 is connected with the interconnect 600, a source electrode (not illustrated) to be connected with the source region 322, a drain electrode (not illustrated) to be connected with the drain region 324, etc. may also be connected with the second interconnect 600 by way of a contact (not illustrated) identical with the contact 620, a local interconnect (not illustrated), and a via (not illustrated).

Actually, a plurality of semiconductor devices 300 identical with those in FIG. 3 are formed in regions not illustrated in FIG. 1A, to form a logic circuit or a circuit of a memory device, etc.

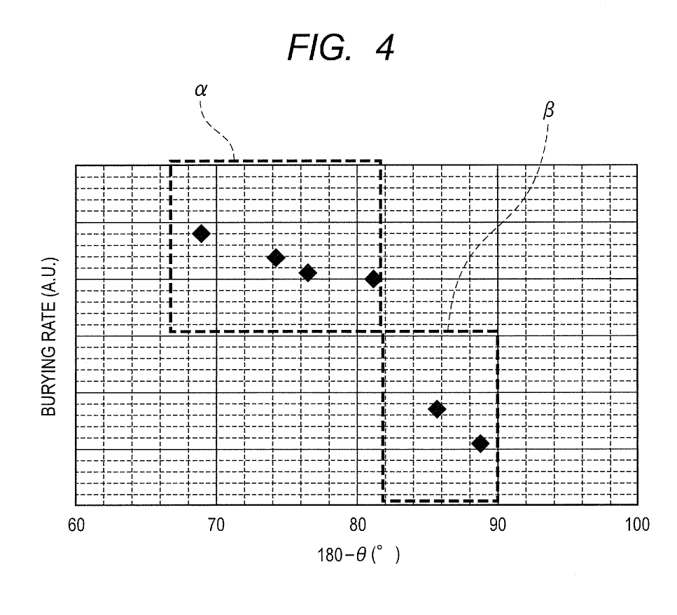

Then, an optimal range for the angle θ₁ formed between the lateral side of the first via 420 and the bottom of the first via 420 and the angle θ₂ formed between the lateral side of the first interconnect 440 and the bottom of the first interconnect 440 is to be described with reference to FIG. 4. FIG. 4 is a graph showing a relation of the angle formed between the lateral side and the bottom in the via or the interconnect to a metal burying rate.

In FIG. 4, the angle formed between the lateral side and the bottom of a via or interconnect trench formed in the first substrate 100 is defined generally as 0 (corresponding to θ₁, θ₂ in FIG. 1B) irrespective of particular first via 420 or first interconnect 440, and the abscissa represents 180-θ (unit “°” in the graph. In the following text, angle is represented as “degree”). The ordinate represents the burying rate when the metal is buried in the via or the interconnect trench.

As shown in FIG. 4, the metal burying rate monotonically decreases relative to 180-θ. In other words, the metal burying rate increases along with increase in the angle θ formed between the lateral side and the bottom in the first via 420 and the first interconnect 440.

Further, as shown in FIG. 4, two regions of different rates are present for the metal burying rate, at 83 degrees of 180-θ being as a boundary. One of the regions where the metal burying rate is high is referred to as an α region and the other region where the metal burying rate is low is referred to as a β region. 180-θ is 83 degrees or less in the α region, while 180-θ is 83 degrees or more and 90 degrees or less in the β region.

As described above, the first via 420 has an inclined portion in which the angle θ₁ formed between the lateral side of the first via 420 and the bottom of the first via 420 is larger than the angle θ₂ formed between the lateral side of the first interconnect 440 and the bottom of the first interconnect 440. Thus, the metal burying rate can be increased more in the first via hole 430 than that in the first interconnect trench 450 in a metal burying step to be described later.

Accordingly, it is preferred that the angle θ₁ formed between the lateral side of the first via 420 and the bottom of the first via 420 in the inclined portion is in the α region and the angle θ₂ formed between the lateral side of the first interconnect 440 and bottom of the first interconnect 440 is in the β region. In this case, since the burying rate in the first via 420 can be made higher than the burying rate in the first interconnect 440, the burying time in the first via 420 and the burying time in the first interconnect 440 can be made closer. Therefore, it is possible to prevent that the first interconnection 440 is buried earlier than the first via 420 and the upper surface of the first interconnect 440 is raised more than the upper surface of the first via 420.

That is, 180-θ₁ is 75 degrees or more and 83 degrees or less and 180-θ₂ is 85 degrees or more and 90 degrees or less. More preferably, 180-θ₁ is 79 degrees or more and 83 degrees or less, and 180-θ₂ is 85 degrees or more and 87 degrees or less.

In other words, the angle θ₁ formed between the lateral side of the first via 420 and the bottom of the first via 420 is 97 degrees or more and 105 degrees or less in the inclined portion, and the angle θ₂ formed between the lateral side of the first interconnect 440 and the bottom of the first interconnect 440 is 90 degrees or more and 95 degrees or less. More preferably, the angle θ₁ formed between the lateral side of the first via 420 and the bottom of the first via 420 is 97 degrees or more and 101 degrees or less in the inclined portion, and the angle θ₂ formed between the lateral side of the first interconnect 440 and the bottom of the first interconnect 440 is 93 degrees or more and 95 degrees or less.

When the angles θ₁ and θ₂ are within the range described above, the burying rate of the metal in the first interconnect trench 450 can be made lower and the burying rate of the metal in the first via hole 430 can be made higher. The angle θ₁ is defined to 105 degrees or less because, otherwise, the range occupied by the inclined portion in the plan view is widened and, as a result, the area at the bottom in the first via 420 is decreased. On the other hand, the angle θ₂ is defined to 90 degrees or more because, otherwise, not only the metal burying rate is lowered extremely but also voids may possibly be formed in a reverse tapered shape.

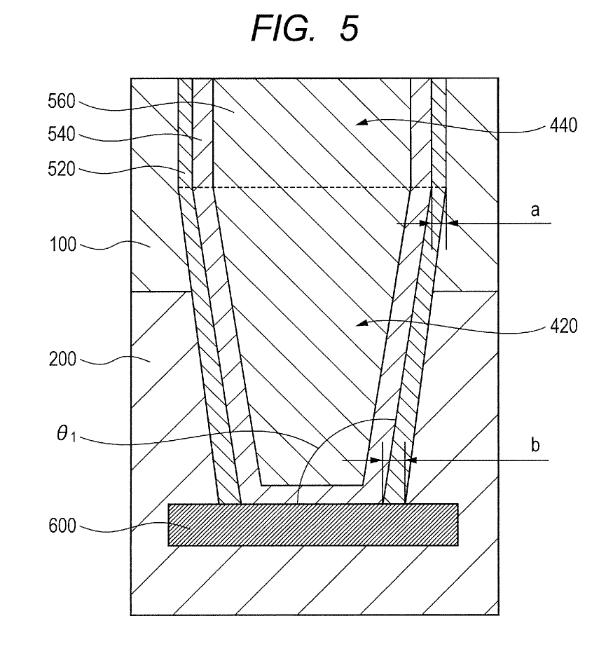

Then, a liner insulating film 520 is to be described with reference to FIG. 5. FIG. 5 is an enlarged cross sectional view of the via shown in FIG. 1B.

As shown in FIG. 5, the liner insulating film 520 is disposed between a first substrate 100 and a barrier metal layer 540. In the liner insulating film 520, the thickness a (nm) on one end of the first via 420 and the thickness b (nm) on the other end of the first via 420 are in a relation: b−a≧7.

When the first via 420 is independent not being connected with the first interconnect 440, “one end of the first via 420” mentioned herein means a portion where the first via 420 defines a surface identical with the upper surface of the first substrate 100. On the other hand, when the first via 420 is connected with the first interconnect 440, the one end means a portion where the first via 420 is in contact with the first interconnect 440.

When the first via 420 is connected with the second interconnect 600, “the other end of the first via 420” mentioned herein means a portion where the first via 420 is in contact with the second interconnect 600.

Pin holes are tended to be formed in the liner insulating film 520 on the other end (on the side of the bottom) of the first via 420. When pin holes are formed, the first via 420 is short circuited to the first substrate 100 to cause insulation failure. Further, it may possibly cause also insulation failure such as migration of the metal 560 of the first via 420. Therefore, a dense liner insulating film 520 with no pin holes is formed on the other end of the first via 420 by defining the configuration of the thickness of the liner insulating film 520 as described above. Therefore, insulation failure described above can be suppressed.

The angle on the lateral side of the first via 420 may be changed at the boundary between the first substrate 100 and the first interlayer insulating film 200. It may suffice that the angle θ₁ formed between the lateral side of the first via 420 and the bottom of the first via 420 on the side of the first substrate 100, and the angle θ₁ formed between the lateral side of the first via 420 and the bottom of the first via 420 on the side of the first interlayer insulating film 200 is within the range of 97 degrees or more and 105 degrees or less as described above. In the etching step for forming a via hole (422) to be described later, an etching rate may be different between the first substrate 100 and the first interlayer insulating film 200. Even when the angle θ₁ changes at the boundary between the first substrate 100 and the first interlayer insulating film 200, the effect of this embodiment can be attained so long as the angle is within the range described above.

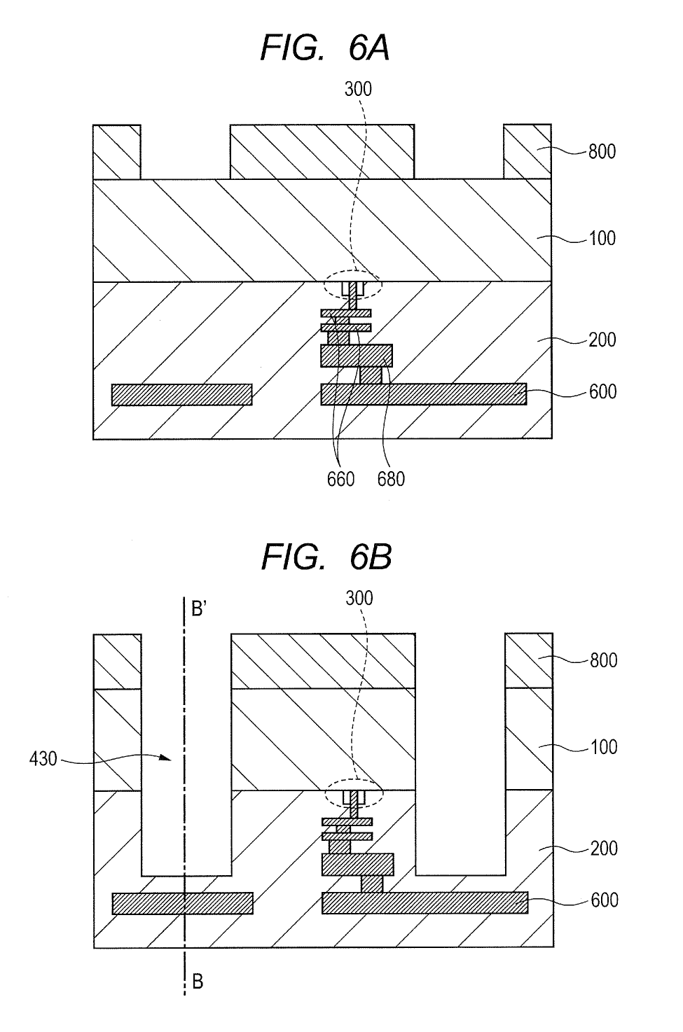

Then, a method of manufacturing the semiconductor device according to the first embodiment is to be described with reference to FIG. 6 to FIG. 10. The method of manufacturing the semiconductor device according to the first embodiment includes the following steps. At first, a first via hole 430 penetrating a first substrate 100 is formed from the first surface of the first substrate 100 and a first interconnect trench 450 connected with one end of at least one or more first via holes 430 is formed (hereinafter referred to as an etching step). Then, a first via 420 and a first interconnect trench 440 are formed by burying a metal 560 in the first via hole 430 and in the first interconnect trench 450 (hereinafter referred to as a metal burying step). In the etching step, an inclined portion is formed in the first via hole 430 where an angle θ₁ formed between the lateral side and the bottom of the first via hole 430 is larger than an angle θ₂ formed between the lateral side of the first interconnect trench 450 and the bottom of the first interconnect trench 450. Details are to be described below.

At first, as shown in FIG. 6A, a first substrate 100 in which a semiconductor device 300, a local interconnect 660, a local interconnect 680, etc. are formed on the side of the second surface is prepared. In the following drawings, reference numerals for the local interconnect 660 and the local interconnect 680 are not shown.

Before the etching step to be described later, a second interconnect 600 is formed in the first substrate 100 on the side of the second surface opposing the first surface. As shown in FIG. 6A, the second interconnect 600 may be formed so as to be buried in a first interconnect insulating film 200.

Then, a resist film 800 is deposited over the first surface of the first substrate 100. Then, an opening for forming a first via hole 430 is formed to the resist film 800 by exposure and development.

Then, as shown in FIG. 6B, a first via hole 430 penetrating the first substrate 100 from the first surface of the first substrate 100 is formed by RIE (Reactive Ion Etching). In this case, a first via hole 430 is formed penetrating the first substrate 100 and etching a portion of the first interlayer insulating film 200. The first via hole 430 is formed by repeating etching and cleaning. Specifically, etching and cleaning are repeated 8 times or more.

In this state, the first via hole 430 is formed in a range not reaching the second interconnect 600. This can suppress oxidation of the second interconnect 600 in the ashing step of the resist film 800.

In the etching step, an intermediate shape of an inclined portion is formed as the first via hole 430 where the angle θ₁ formed between the lateral side and the bottom is larger than the angle θ₂ formed between the lateral side of the first interconnect trench 450 and the bottom of the first interconnect trench 450 to be described later. It may suffice that the shape of the inclined portion described above is formed after etching as far as the first interconnect trench 450. That is, it is not always necessary to form the inclined portion described above in this stage. Accordingly, an intermediate shape of the inclined portion is formed as the first via hole 430 such that the shape after the etching step to be described later gives a desired shape.

Then, the resist film 800 is removed by ashing.

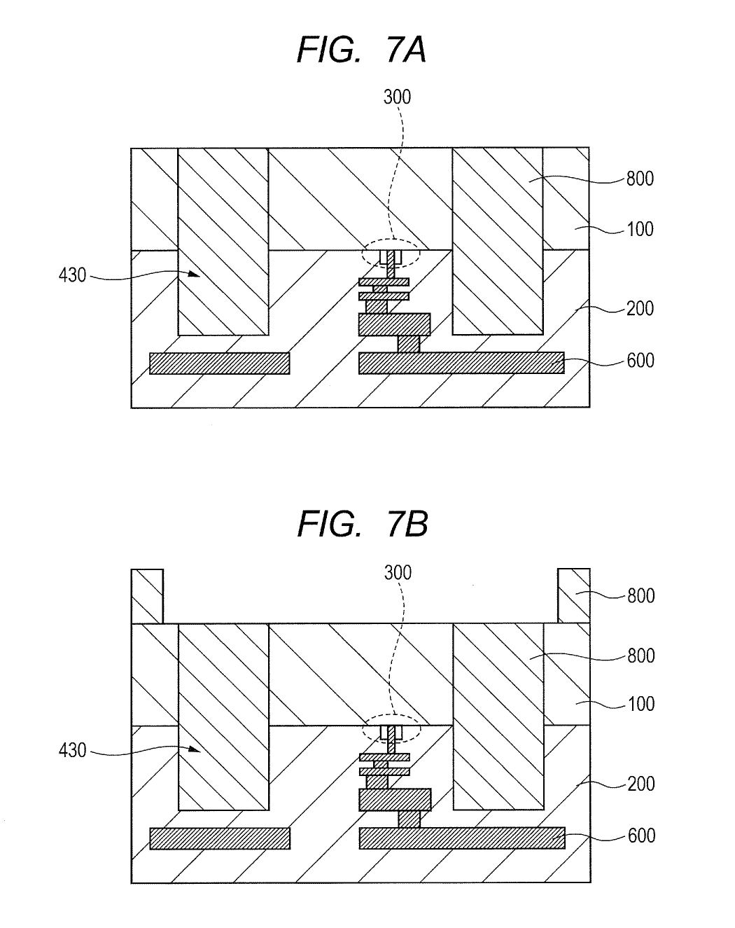

Then, as shown in FIG. 7A, a resist film 800 is buried inside the first via hole 430. In this case, since the resist film 800 is actually formed also over the first substrate 100 in FIG. 7A, the resist film 800 is planarized by etching back. Etching back may not be performed.

As shown in FIG. 7B, a resist film 800 is deposited over the first surface of the first substrate 100. Then, an opening for forming a first interconnect trench 450 is formed in the resist film 800 over the first substrate 100 by exposure and development.

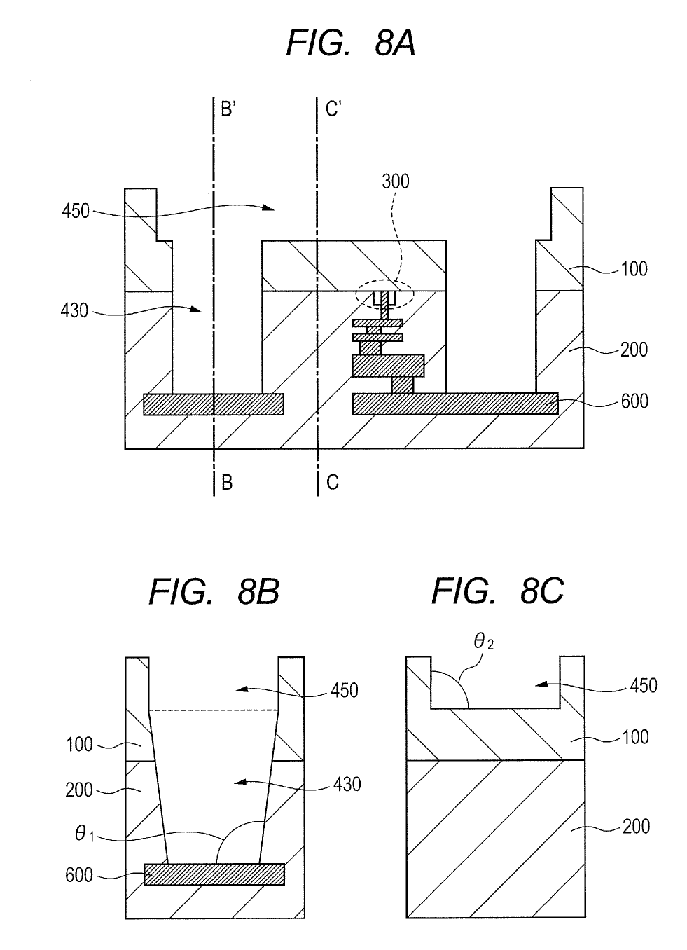

Then, as shown in FIG. 8A, the first substrate 100 is etched by RIE thereby forming an intermediate trench (not illustrated) in the first interconnect trench 450 etched to an intermediate portion. Then, the resist film 800 is removed by ashing. Then, the first via hole 430 is etched by etching back the entire surface till it is in contact with the second interconnect 600. Thus, the other end of the first via hole 430 is connected with the second interconnect 600. Simultaneously, the intermediate trench etched to an intermediate portion (not illustrated) in the first interconnect trench 450 is further etched to a desired depth of the first interconnect trench 450.

Then, as shown in FIG. 8B and FIG. 8C, an inclined portion is formed in the first via hole 430 where an angle θ₁ formed between the lateral side and the bottom of the first via 430 is larger than an angle θ₂ formed between the lateral side of the first interconnect trench 450 and the bottom of the first interconnect trench 450 to be described later in this etching step.

As shown in FIG. 8B, the inclined portion is formed such that the angle θ₁ formed between the lateral side of the first via 420 and the bottom of the first via 420 is, for example, 97 degrees or more and 105 degrees or less. Therefore, the burying rate of the metal 560 in the first via hole 430 can be made higher than that in the first interconnect trench 450 in the metal burying step described later.

As shown in FIG. 8C, a first interconnect trench 450 is formed such that an angle θ₂ formed to the lateral side of the first interconnect trench 450 and the bottom of the first interconnect trench 450 is, for example, 90 degrees or more and 97 degrees or less. Therefore, the burying rate of the metal 560 in the first interconnect trench 450 can be made lower than in the first via hole 430.

As described above, the first interconnect trench 450 is formed after forming the first via hole 430 (the above is the etching step). If the first interconnect trench 450 is formed previously, it is difficult to maintain the shape of the first interconnect trench 450 to the angle described above when the first via hole 430 is etched. Accordingly, by forming the first via hole 430 previously, the first via hole 430 and the first interconnect trench 450 of the shape described above can be formed easily.

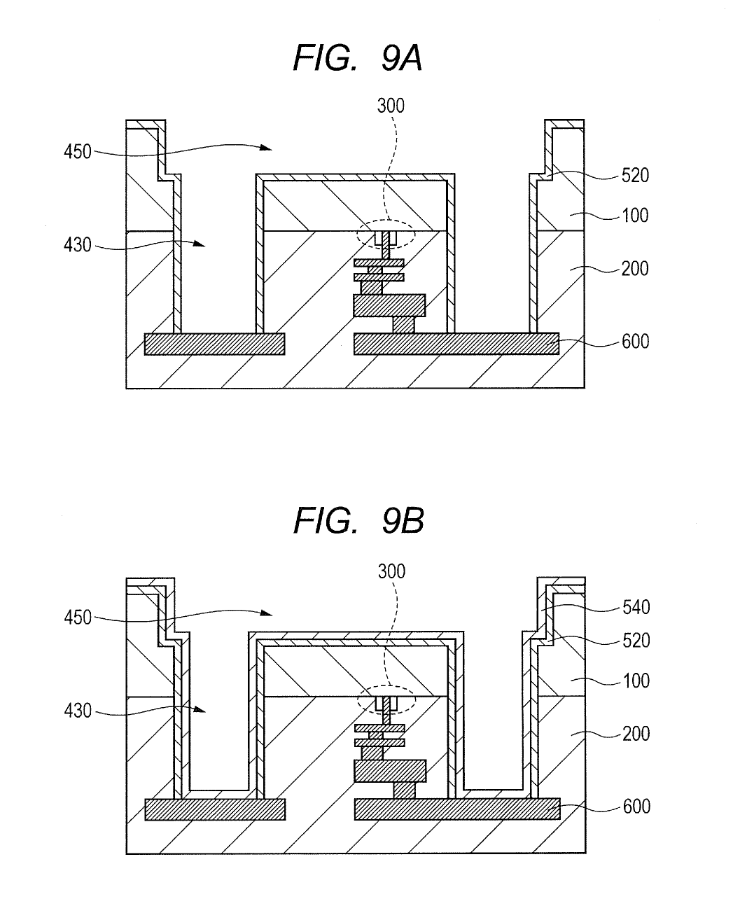

Then, as shown in FIG. 9A, a liner insulating film 520 is formed on the lateral side and on the bottom inside the first via hole 430 and the first interconnect trench 450 and on the first substrate 100. The liner insulating film 520 is formed in this step by CVD (Chemical Vapor Deposition) or thermal oxidation of the first substrate 100.

Since the first via hole 430 has a high aspect ratio, the liner insulating film 520 tends to be formed to a large thickness on one end and to a smaller thickness on the other end of the first via hole 430. In this embodiment, an inclined portion is formed to the first via hole 430 such that the angle θ₁ formed between the lateral side and the bottom of the first via hole 430 is larger than the angle θ₂ formed between the lateral side of the first interconnect trench 450 and the bottom of the first interconnect trench 450. Thus, the liner insulating film 520 can be deposited to a large thickness also on the side wall at the other end of the first via hole 430.

Then, the liner insulating film 520 at the bottom of the first via hole 430, that is, at a portion where the first via hole 430 is in contact with the second interconnect 600 by etching back. Thus, the second interconnect 600 is exposed inside the first via hole 430.

As shown in FIG. 5, the liner insulating film 520 is formed such that the thickness a (nm) on one end of the first via 420 and the thickness b (nm) on the other end of the first via 420 of the liner insulating film 520 are in a relation: b−a≧7.

Then, as shown in FIG. 9B, a barrier metal layer 540 is formed on the bottom of the first via hole 430, the lateral side of the first via hole 430 and the lateral side and the bottom of the first interconnect trench 450 covered by the liner insulating film 520, and on the first substrate 100 by sputtering.

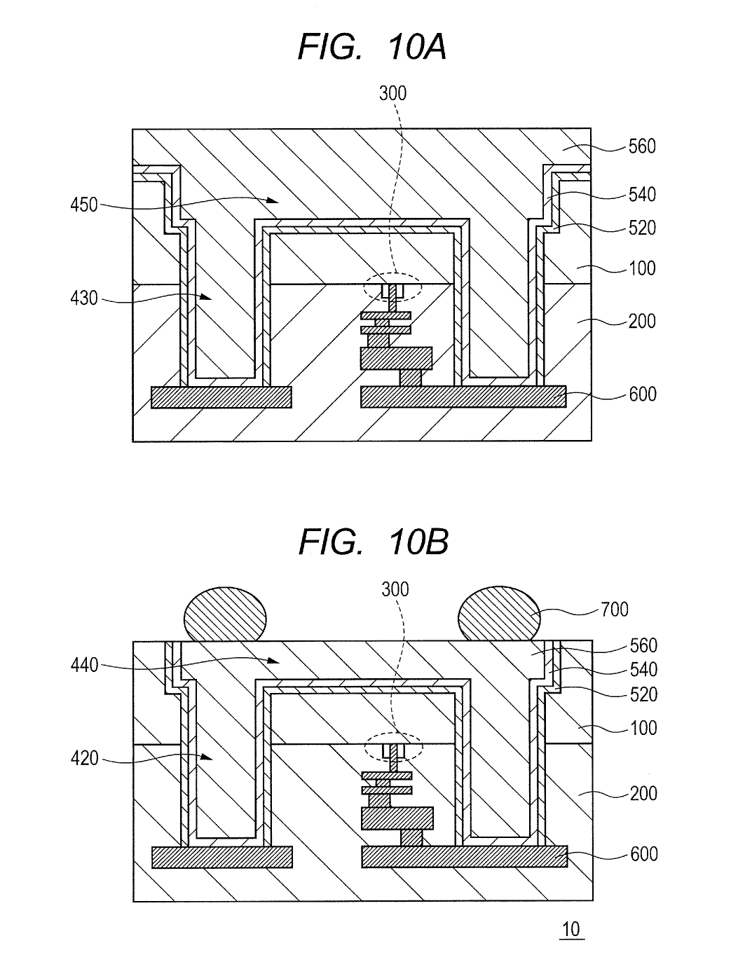

Then, as shown in FIG. 10A, a metal 560 is buried by a plating method inside the first via hole 430 and the first interconnect trench 450. Preferably, a temperature is 20° C. or higher and 30° C. or lower and a current value is 3 A or more and 20 A or less as plating conditions. Thus, the burying rate shown in FIG. 4 can be reproduced.

As described above, the burying rate of the metal 560 into the first via hole 430 is made higher and, on the other hand, the burying rate of the metal 560 into the first interconnect trench 450 is made lower by adjusting the shape of the first via hole 430 and the first interconnect trench 450. Accordingly, there is no large difference of unevenness after plating between a portion just above the first via hole 430 and a portion just above the first interconnect trench 450 at the first surface of the first substrate 100 and no undesired effect is given on the subsequent CMP step.

Then, the first substrate 100 is planarized on the side of the first surface by CMP. With the procedures described above, the first via 420 and the first interconnect 440 are formed (the above is the metal burying step).

As shown in FIG. 10B, a first bump electrode 700 connected with the first via 420 or the first interconnect 440 is formed over the first interconnect 440 of the first substrate 100. In this embodiment, the first bump electrode 700 is formed just above the first via 420.

As described above, the semiconductor device 10 according to this embodiment is obtained.

Then, the effect of the first embodiment is to be described.

According to this embodiment, the first via 420 has an inclined portion where the angle θ₁ formed between the lateral side and the bottom of the first via 420 is larger than the angle θ₂ formed between the lateral side and the bottom of the first interconnect 440. This can increase the burying rate of the metal 560 in the first via hole 430 than that in the first interconnect trench 450 in the subsequent metal burying step. That is, the burying time of the first via 420 can be made closer to the burying time in the first interconnect 440. Accordingly, the first surface of the first substrate 100 after burying the metal 560 can be planarized, which can be further planarized uniformly in CMP.

Therefore, this embodiment can provide a semiconductor device 10 having the first via 420 and the first interconnect 440 for supplying a high current and having a planar first surface in which the first surface where the first via 420 and the first interconnect 440 are formed.

### Second Embodiment

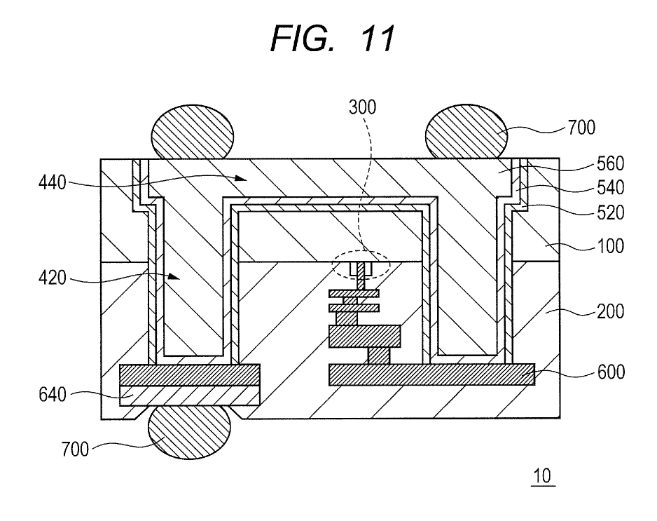

FIG. 11 is a cross sectional view showing a configuration of a semiconductor device 10 according to a second embodiment. The second embodiment is identical with the first embodiment except that a first bump electrode 700 connected with a second interconnect 600 is provided over a second surface of a first substrate 100. The second embodiment is to be described specifically.

As shown in FIG. 11, an electrode pad 640 is formed over the second interconnect 600 of the first substrate 100 on the side of the second surface. The electrode pad 640 is formed, for example, of Al.

Further, a protective film (not illustrated), a polyimide film (not illustrated), etc. are formed on the outer peripheral surface of the electrode pad 640. Both of them are shown as a portion of the first interlayer insulating film 200.

Further, a first bump electrode 700 is formed on the electrode pad 640. For the first bump electrode 700 on the side of the second surface, an identical material with that of the first bump electrodes 700 on the side of the first surface can be used. However, the first bump electrode 700 on the side of the second surface may also be formed of a material for which the mounting temperature is different from that for the first bump electrode 700 on the side of the first surface. Further, the first bump electrode 700 on the side of the second surface may also be a bonding wire.

According to the second embodiment, the first bump electrode 700 connected with the second interconnect 600 is formed to the first substrate on the second surface opposing the first surface. This enables external connection from both sides of the first surface and the second surface of the first substrate 100. For example, a printed wiring board, etc. can be mounted on both sides.

### Third Embodiment

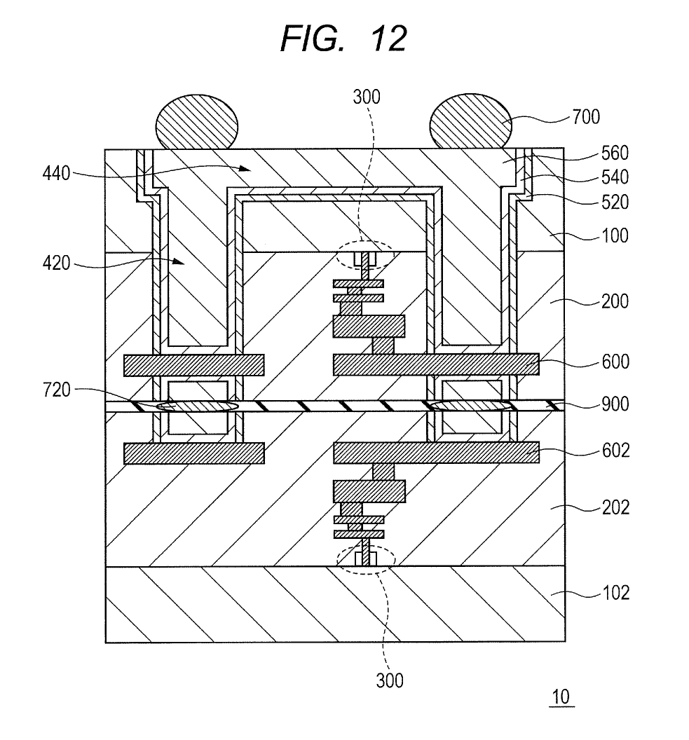

FIG. 12 is a cross sectional view showing a configuration of a semiconductor device 10 according to a third embodiment. The third embodiment is identical with the first embodiment except for the following configuration. A second substrate 102 having a third interconnect 602 at the surface on the side of the first substrate 100 is joined to the first substrate 100 on the side of the second surface opposing the first surface. Further, the second interconnect 600 is connected by way of a bump 720 (for example, a microbump) to the third interconnect 602. This third embodiment is to be described specifically.

As shown in FIG. 12, a joining layer 900 is formed over a first interlayer insulating film 200 to the first substrate 100 on the side of the second surface. For the joining layer 900, a thermosetting resin is used. The thermosetting resin comprises, for example, an epoxy resin or a nonconductor film. Further, as the method of forming the joining layer 900, a method of performing thermal oxidation after joining the first substrate 100 and the second substrate 102, or a method of connecting them by activating the surfaces of the first substrate 100 and the second substrate 102 by an Ar beam.

Further, the second substrate 102 is joined by way of the joining layer 900 to the first substrate 100 on the side of the second surface. In this case, the first substrate 100 is joined to the second substrate 102 on the surface where the third interconnect 602 to be described later is formed.

In the same manner as in the first substrate 100, a semiconductor device 300, etc. are formed in the second substrate 102. A second interlayer insulating film 202 is formed over the second substrate 102. Further, a third interconnect 602 is formed in the uppermost layer of the second interlayer insulating film 202.

In this embodiment, a first via 420 is formed so as to penetrate the first substrate 100 in the same manner as in the first embodiment. The other end of the first via 420 is connected with the second interconnect 600.

A via (unnumbered), for example, for connection with a third interconnect 602 of the second substrate 102 is formed to the second interconnect 600 on the side of the second substrate 102. On the other hand, a via (unnumbered) for connection with the second interconnect 600 of the substrate 100 is formed, for example, to the third interconnect 602 on the side of the first substrate 100.

Further, the second interconnect 600 is connected by way of a bump 720 with the third interconnect 602 formed in the second substrate 102 at the surface on the side of the first substrate 100. This can supply a current from the first surface of the first substrate 100 to the third interconnect 602, etc. in the second substrate 102.

The bump 720 is disposed in the joining layer 900. “bump 720” referred to herein means, for example, a microbump. As the material of the bump 720, a material identical, for example, with that of the first bump electrode 700 can be used. Further, since the bump 720 is connected with the fine second interconnect 600 and third interconnect 602, it is preferably smaller than the first bump electrode 700, etc.

While description has been made to a configuration where vias are disposed to the second interconnect 600 on the side of the second substrate 102 and to the third interconnect 602 on the side of the first substrate 100 for connecting bath interconnects, the second interconnect 600 and the third interconnect 602 may be connected with each other directly by way of the bump 720.

In the same manner as in the first embodiment, the first via 420 has an inclined portion where the angle θ₁ formed between the lateral side of the first via 420 and the bottom of the first via 420 is larger than the angle θ₂ formed between the lateral side of the first interconnect 440 and the bottom of the first interconnect 440.

The third interconnect 602 is a power supply interconnect for supplying a current, for example, to the semiconductor device 300 or a ground interconnect disposed in the second substrate 102. As described above, the third interconnect 602 can be supplied with a high current from the first via 420 since this is connected with the first via 420 by way of the bump 720 and the second interconnect 600.

As described above, the first via 420 can supply a high current to both of the first substrate 100 and the second substrate 102.

The first substrate 100 has, for example, a logic circuit. The second substrate 102 has, for example, a memory device for storing signals transmitted from the logic circuit. Thus, various kinds of substrates having devices or circuits necessary for forming the memory device can be stacked in a space-saving manner.

Then, a method of manufacturing the semiconductor device 10 according to the third embodiment is to be described. In addition to the manufacturing method of the first embodiment, a second substrate 102 having a third interconnect 602 at the first surface on the side of the first substrate 100 is prepared. Further, a second substrate 102 is joined to the first substrate on the side of the second surface of the first substrate 100 opposing the first surface (joining step). In the joining step, the second interconnect 600 is connected by way of the bump to the third interconnect 602. The method is to be described specifically while omitting the description for the portions identical with those of the first embodiment.

At first, in the same manner as in the first embodiment, the intermediate body of the semiconductor device 10 in the state shown in FIG. 10B is formed to the first substrate 100.

Then, a via (unnumbered), for example, connected at one end to the second interconnect 600 is formed over the second interconnect 600 in the first interlayer insulating film 200. The via is disposed so as to be connected with the third interconnect of the second substrate 102.

Then, the second substrate 102 having the third interconnect 602 at the first surface on the side of the first substrate 100 is prepared. In addition, a semiconductor device 300 is formed, for example, in the first substrate 100. The third interconnect 602 may also be buried in the second interlayer insulating film 202.

Then, a via (unnumbered), for example, connected at one end with the third interconnect 602 is formed in the second interlayer insulating film 202 over the third interconnect 602. The via is disposed so as to be connected with the second interconnect 600 of the first substrate 100.

Then, the second substrate 102 is joined by way of the joining layer 900 to the first substrate 100 on the side of the second surface opposing the first surface (joining step). In this joining step, the second interconnect 600 is connected by way of the bump to the third interconnect 602.

As described above, the semiconductor device 10 according to the third embodiment is obtained.

According to the third embodiment, the second substrate 102 is joined to the first substrate 100 on the side of the second surface opposing the first surface. Thus, a plurality of substrates can be stacked in a space-saving manner.

### Fourth Embodiment

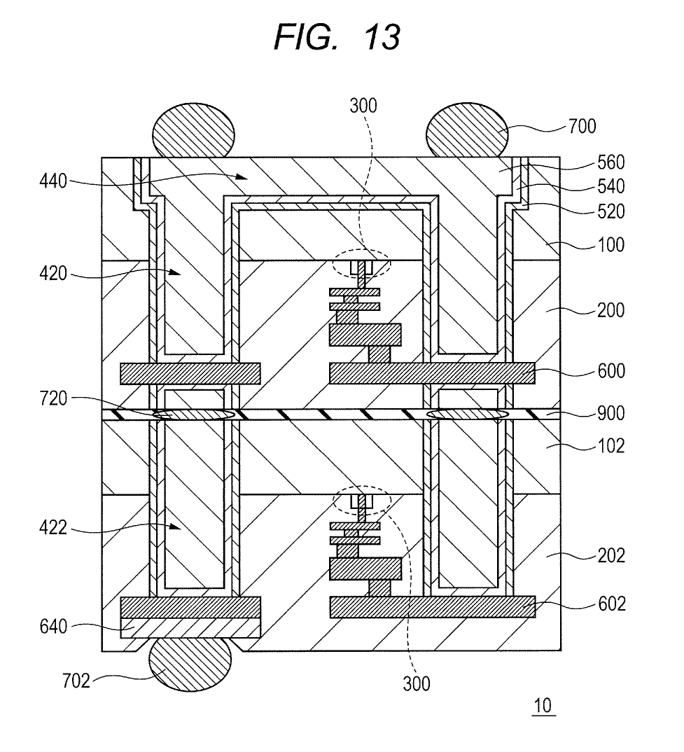

FIG. 13 is a cross sectional view showing a configuration of a semiconductor device 10 according to a fourth embodiment. The fourth embodiment is identical with the first embodiment or the third embodiment except for the following configurations. A second substrate 102 is joined to a first substrate 100 on the side of the second surface opposing the first surface. The second substrate 102 has a second via 422 penetrating the second substrate 102 from the first surface on the side of the first substrate 100 and forming at one end a surface identical with the first surface on the side of the first substrate 100, and a third interconnect 602 disposed on the side opposing the first substrate 100 and connected with the other end of a second via 422. Further, a second interconnect 600 is connected with one end of a second via 422 by way of a bump 720 (for example, microbump). This embodiment is to be described specifically.

As shown in FIG. 13, a joining layer 900 is formed over the first interlayer insulating film 200 to the first substrate 100 on the side of the second surface.

Further, the second substrate 102 is joined by way of the joining layer 900 to the first substrate 100 on the side of the second surface. In the fourth embodiment, unlike the third embodiment, the first substrate 100 is joined to the second substrate 102 on the side opposing the surface where the third interconnect 602 is formed.

In the second substrate 102, the second via 422 penetrates the second substrate 102 from the first surface on the side of the first substrate 100. Further, one end of the second via 422 forms a surface identical with the first surface on the side of the first substrate 100.

In the second substrate 102, the third interconnect 602 is disposed on the side opposing the first substrate 100. The third interconnect 602 is connected with the other end of the second via 422.

Further, the second interconnect 600 disposed to the first substrate 100 on the side of the second surface is connected by way of the bump 720 to one end of the second via 422. In this embodiment, a via (unnumbered) is disposed, for example, in the same manner as in the third embodiment to the second interconnect 600 on the side of the second substrate. Accordingly, the second interconnect 600 is connected with one end of the first via 422 by way of the via and the bump 720. Thus, a current can be supplied from the side of the first surface of the first substrate 100 to the third interconnect 602, etc. in the second substrate 102. The second interconnect 600 and the second via 422 may also be connected with each other not by way of the via but directly at their one ends by way of the bump 720.

The bump 720 is disposed in the joining layer 900. For the bump 720, the same material as in the third embodiment can be used.

An electrode pad 640 is formed, for example, over the third interconnect 602. Further, a protective film (not illustrated), a polyimide film (not illustrated), etc. are formed, for example, on the outer peripheral surface of the electrode pad 640.

Further, a second bump electrode 702 disposed at the surface on the side opposing the first substrate 100 and connected with the third interconnect 602 may also be disposed over the second substrate 102. This enables external connection to a printed wiring board, etc. also from the surface of the second substrate 102 on the side opposing the first substrate 100.

A method of manufacturing the semiconductor device 10 according to the fourth embodiment is to be described. The method of manufacturing the semiconductor device 10 according to the fourth embodiment is identical with that of the first embodiment or the third embodiment except for the following configurations. In addition to the manufacturing method of the first embodiment, a second substrate 102 is prepared. The second substrate 102 is joined to the first substrate 100 on the side of the second surface opposing the first surface (joining step). In the joining step, the second interconnect 600 is connected by way of the bump to one end of the second via 422. The method is to be described specifically while omitting the description for the portions identical with those of the third embodiment.

At first, in the same manner as in the third embodiment, the intermediate body of the semiconductor device 10 in the state shown in FIG. 10B is formed to the first substrate 100. Further, a via (unnumbered) to be connected, for example, at one end with the second interconnect 600 is formed in the first interlayer insulating film 200 over the second interconnect 600.

Then, the following second substrate 102 is prepared. The second substrate 102 has a second via 422 penetrating the second substrate 102 from the first surface on the side of the first substrate 100 and forming at one end a surface identical with the first surface on the side of the first substrate 100, and a third interconnect 602 disposed on the side opposing the first substrate 100 and connected with the other end of the second via 422.

The second via 422 is disposed previously so as to be connected with the second interconnect 600. That is, the second via 422 is disposed so as to overlap the second interconnect 600 in a plan view. Other configurations are identical with those of the second substrate 102 in the third embodiment.

The step of preparing the second substrate 102 is identical with the first embodiment except for not forming the first interconnect 440. Accordingly, the angle θ₁ formed between the lateral side of the first via 420 and the bottom of the first via 420 (surface in contact with the third interconnect 602 in this embodiment) may also be 97 degrees or more and 105 degrees or less.

Then, the second substrate 102 is joined by way of the joining layer 900 to the first substrate 100 on the side of the second surface opposing the first surface (joining step). In the joining step, the second interconnect 600 is connected by way of the bump to one end of the via 422.

Then, a second bump electrode 702 connected with the third interconnect 602 may also be formed to the second substrate 102 on the surface opposing the first substrate 100.

As described above, a semiconductor device 10 according to the fourth embodiment is obtained.

In the fourth embodiment, the same effect as in the third embodiment can be obtained.

### Fifth Embodiment

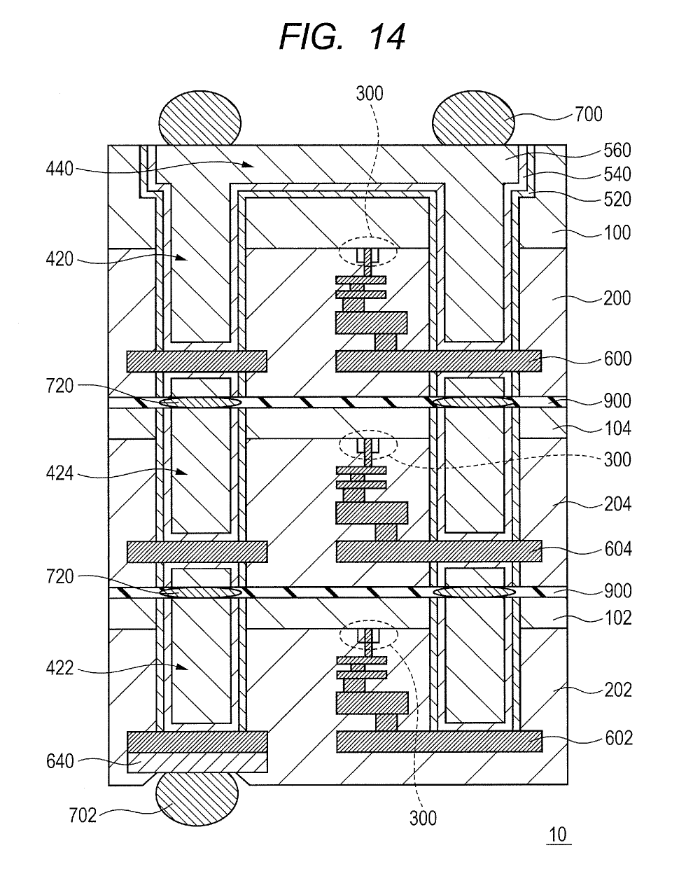

FIG. 14 is a cross sectional view showing the configuration of a semiconductor device 10 according to a fifth embodiment. The fifth embodiment is identical with the third and fourth embodiments except for the following configurations. At least one third substrate 104 is joined between a first substrate 100 and a second substrate 102. The third substrate 104 has a third via 424 penetrating the third substrate 104 from the first surface of the third substrate 104 and forming at one end a surface identical with the first surface of the third substrate 104, and a fourth interconnect 604 disposed in the third substrate 104 over the second surface opposing the first surface and connected with the other end of the third via 424. Further, one end of the third via 424 or the fourth interconnect 604 is connected respectively by way of a bump 720 to a second interconnect 600 of the first substrate 100 or one end of a second via 422 in the second substrate 102. The fifth embodiment is to be described specifically.

As shown in FIG. 14, the upper and lower first substrate 100 and second substrate 102 have the same configuration as that of the fourth embodiment.

At least one third substrate 104 is provided between the first substrate 100 and the second substrate 102. The third substrate 104 is joined at the contact face with each of the first substrate 100 and the second substrate 102 by way of a joining layer 900. The third substrate 104 may be provided by one or in plurality.

Further, for the third substrate 104, the same substrate as the first substrate 100 or the second substrate 102 can be used. In this embodiment, a semiconductor device 300, a third interlayer insulating film 204, and a fourth interconnect 604 are formed in the interconnect 104.

In the third substrate 104, a third via 424 penetrates the third substrate 104 from the first surface of the third substrate 104. Further, one end of the third via 424 forms a surface identical with the first surface of the third substrate 104.

Further, a fourth interconnect 604 is disposed in the third substrate 104 over the second surface opposing the first surface. The fourth interconnect 604 is connected with the other end of the third via 424. In this embodiment, a via (unnumbered) is disposed on the side of the second substrate of the fourth interconnect 604.

Further, one end of the third via 424 or the fourth interconnect 604 is connected respectively by way of the bump 720 to the second interconnect 600 of the first substrate 100 or one end of the second via 422 of the second substrate 102. This can supply a high current not only to the first substrate 100 and the second substrate 102 but also to at least one third substrate 104.

For example, in FIG. 14, one end of the third via 424 is connected with the second interconnect 600 in the first substrate 100. Further, the fourth interconnect 604 is connected with one end of the second via 422 in the second substrate 102. On the other hand, the third substrate 104 may be joined in the manner opposite to that described above.

As another modified embodiment, the third interconnect 602 may also be disposed in the second substrate 102 at the first surface on the side of the first substrate 100 as in the third embodiment. Accordingly, one end of the third via 424 or the fourth interconnect 604 may also be connected respectively by way of the bump 720 to the second interconnect 600 of the first substrate 100 or the third interconnect 602 of the second substrate 102.

The first substrate 100 has, for example, a logic circuit. The second substrate 102 and the third substrate 104 have, for example, a memory device for storing signals transmitted from the logic circuit. This enables to stack various kinds of substrates having a device or a circuit necessary for forming the memory device in the space saving manner in the same way as in the third embodiment.

Then, a method of manufacturing the semiconductor device 10 according to the fifth embodiment is to be described. The method of manufacturing the semiconductor device 10 according to the fifth embodiment is identical with that of the third embodiment or the fourth embodiment except for the following configurations. The method of manufacturing the semiconductor device 10 according to the fifth embodiment further has the following steps. The second substrate 102 and at least one third substrate 104 are prepared. Further, the third substrate 104 and the second substrate 102 are joined successively to the first substrate 100 on the side of the second surface opposing the first substrate (joining step). In the joining step, one end of the third via 424 or the fourth interconnect 604 is respectively connected by way of a bump to the second interconnect 600 of the first substrate 100 or one end of the second via 422 of the second substrate 102 by way of the bump. The manufacturing method is to be described specifically while omitting description for the portions identical with those of the third and the fourth embodiments.

At first, the first substrate 100 and the second substrate 102 are prepared in the same manner as in the fourth embodiment.

Then, the following third substrate 104 is prepared. The third substrate 104 has a third via 424 penetrating the third substrate 104 from the first surface of the third substrate 104 and forming at one end a surface identical with the first surface of the third substrate 104, and a fourth interconnect 604 disposed to the third substrate 104 on the second surface opposing the first surface and connected with the other end of the third via 424.

Further, they are previously disposed such that the third via 424 is connected with the second interconnect 600. Other configurations are identical with those of the second substrate 102 in the third embodiment.

The step of preparing the third substrate 104 is identical with the first embodiment except for not forming the first interconnect 440.

Then, the third substrate 104 and the second substrate 102 are joined successively to the first substrate 100 on the side of the second surface opposing the first surface (joining step). In the joining step, one end of the third via 424 or the fourth interconnect 604 is joined respectively by way of the bump to the second interconnect 600 of the first substrate 100 or one end of a second via 422 of the second substrate 102.

As described above, when the third substrate 104 is joined, it is not restricted to the configuration shown in FIG. 14 but may be in a configuration which is turned upside down. Further, also in a case of joining a plurality of the third substrates 104, each of the third substrates 104 may be joined with an optional joining face.

Further as another modified embodiment, the second substrate 102 may be joined such that the third interconnect 602 is disposed to the first surface on the side of the first substrate 100 as in the third embodiment.

Subsequent steps are identical with those in the fourth embodiment.

According to the fifth embodiment, the same effects as those in the third and fourth embodiments can be obtained. Further, according to the fifth embodiment, three or more substrates can be joined in a space-saving manner to provide the semiconductor device 10 having a multiple function.

### Sixth Embodiment

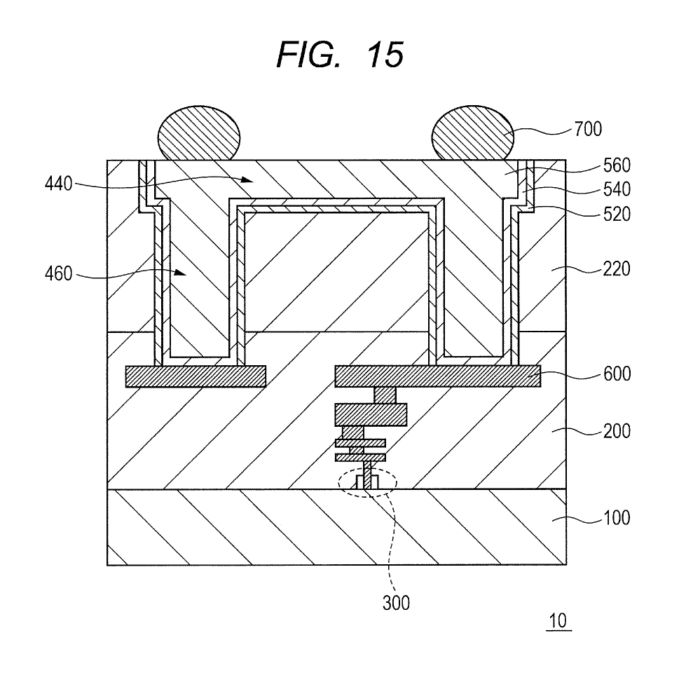

FIG. 15 is a cross sectional view showing a configuration of a semiconductor device 10 according to a sixth embodiment. The six embodiment is identical with the first embodiment except that a first interlayer via 460 and a first interconnect 440 are formed from the side of the first interlayer insulating film 220 disposed over the first substrate 100. The sixth embodiment is to be described specifically.

As shown in FIG. 15, a semiconductor device 300, a first interlayer insulating film 200, and a second interconnect 600 are formed to the first surface of the first surface 100 in the same manner as in the first embodiment. “First surface of the first substrate 100” in the sixth embodiment means a surface where the semiconductor device 300, the first interlayer insulating film 200, etc. are formed.

A first interlayer insulating film 220 is formed over the first interlayer insulating film 200. For the first interlayer insulating film 220, a material identical with that for the first interlayer insulating film 200 can be used. The first interlayer insulating film 220 may be formed of a material different from the first interlayer insulating film 200.

The first interlayer via 460 is formed so as to penetrate the first interlayer insulating film 220. Further, the first interlayer via 460 penetrates the first interlayer insulating film 220 and a portion of the first interlayer insulating film 200. The other end of the first interlayer via 460 is connected with the second interconnect 600.

The first interconnect 440 is buried in the surface of the first interlayer insulating film 220. Further, the first interconnect 440 is connected with one end of at least one first interlayer via 460.

The second interconnect 600 buried in the first interlayer insulating film 220 described above is connected with the other end of the first interlayer via 460.

The first interlayer via 460 has an inclined portion where the angle θ₁ formed between the lateral side of the first interlayer via 460 and the bottom of the first interlayer via 460 is larger than the angle θ₂ formed between the lateral side of the first interconnect 440 and the bottom of the first interconnect 440.

Then, a method of manufacturing the semiconductor device 10 according to the sixth embodiment is to be described. The method of manufacturing the semiconductor device 10 according to the sixth embodiment is identical with that of the first embodiment except that the first interlayer via 460 and the first interconnect 440 are formed from the side of the first interlayer insulating film 220 provided over the first substrate 100. The manufacturing method is to be described specifically while omitting the description for the portions identical with those of the first embodiment.

At first, the first substrate 100 where the semiconductor device 300, the first interlayer insulating film 200 and the second interconnect 600 are formed is prepared. Then, the first interlayer insulating film 220 is formed over the first interlayer insulating film 200.

Then, the first interlayer via hole penetrating the first interlayer insulating film 220 is formed, and a first interconnect trench 450 connected with one end of at least one first interlayer via hole is formed (etching step). The first interlayer via hole is identical with the first via hole 430 in the first embodiment.

In the etching step, the inclined portion is formed to the first interlayer via hole where the angle θ₁ formed between the lateral side and the bottom is larger than the angle θ₂ formed between the lateral side of the first interconnect trench 450 and the bottom of the first interconnect trench 450.

Then, the metal 560 is buried in the first interlayer via hole and the first interconnect trench 450 thereby forming the first interlayer via 460 and the first interconnect 440 (metal burying step).

The subsequent steps are identical with those in the first embodiment.

According to the sixth embodiment, the first interlayer via 460 and the first interconnect 440 can be formed in the same manner as the first via 420 even if the first surface is not the substrate surface of the first substrate 100 as in the first embodiment. This can provide the same effects as those in the first embodiment.

### Seventh Embodiment

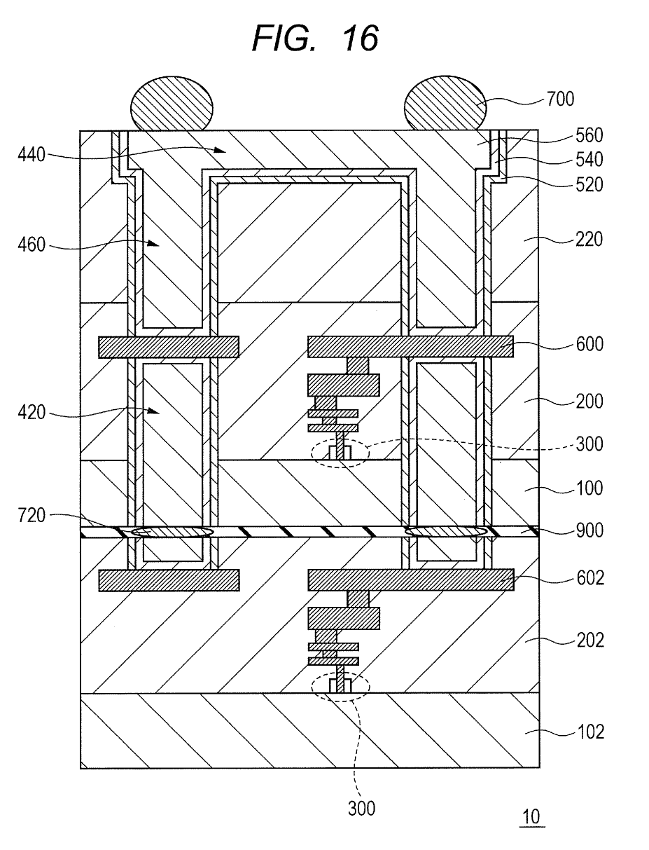

FIG. 16 is a cross sectional view showing the configuration of a semiconductor device 10 according to a seventh embodiment. The seventh embodiment is identical with the third embodiment or the sixth embodiment except for the following configurations. A first substrate has a first substrate via 420 penetrating the first substrate 100 from the second surface opposing the first surface of the first substrate 100 and connected at one end with the second interconnect 600 and forming at the other end a surface identical with the second surface. The seventh embodiment is to be described specifically.

As shown in FIG. 16, the first substrate via 420 penetrates the first substrate 100 from the second surface opposing the first surface. One end of the first substrate via 420 is connected with the lower surface of the second interconnect 600. Further, the other end of the first substrate 420 forms a surface identical with the second surface (rear face) of the substrate 100.

The first substrate via 420 is disposed so as to be connected with a third interconnect 602 of a second substrate 102. That is, the first substrate via 420 is disposed so as to overlap a third interconnect 602 in a plan view.

The first substrate 100 and the surface of the second substrate 102 to which the third interconnect 602 is formed are joined by way of a joining layer 900.

The other end of the first substrate via 420 is connected by way of a bump 720 with the third interconnect 602 of the second substrate 102.

Then, a method of manufacturing the semiconductor device 10 according to the seventh embodiment is to be described. The method of manufacturing the semiconductor device 10 according to the seventh embodiment is identical with that of the third embodiment or the sixth embodiment except for the following configurations.

At first, in the same manner as the sixth embodiment, the intermediate body of the semiconductor device 10 in the state shown in FIG. 15 is prepared.

Then, the first substrate via 420 is formed so as to penetrate the first substrate 100 from the second surface opposing the first surface and to be connected at one end with the second interconnect 600 and such that the other end on the side of the second surface forms a surface identical with the second surface.

The step of forming the first substrate via 420 may be performed before the step of forming the first interlayer via 460.

Other steps are identical with those in the third embodiment.

According to the seventh embodiment, the effects identical with those of the third embodiment can be obtained.

### Eighth Embodiment

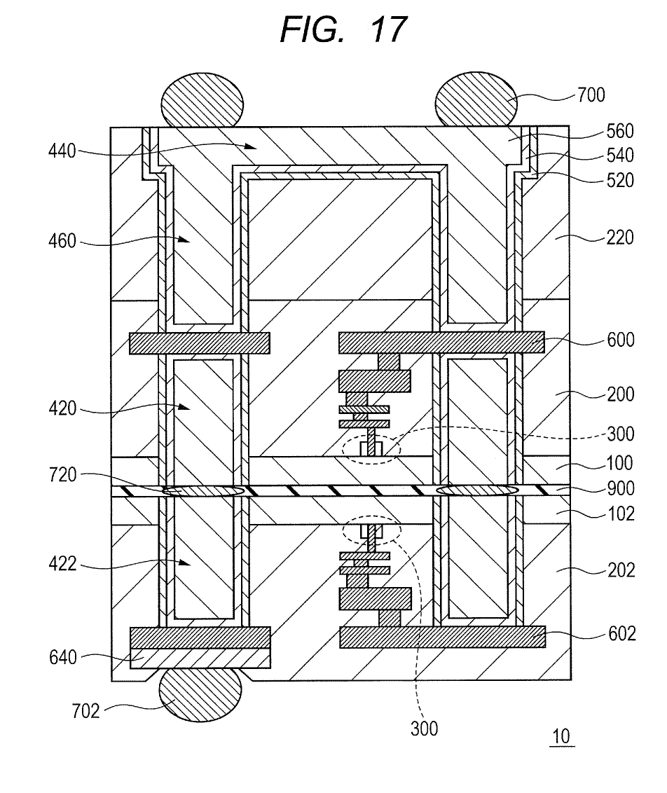

FIG. 17 is a cross sectional view showing the configuration of a semiconductor device 10 according to an eighth embodiment. The eighth embodiment is identical with the fourth embodiment except that a first substrate 100 is identical with that of the seventh embodiment. The eighth embodiment is to be described specifically.

As shown in FIG. 17, the first substrate 100 is joined with the surface of a second substrate 102 at the surface opposing the surface to which the third interconnect 602 is formed by way of a joining layer 900.

In the same manner as in the seventh embodiment, a first substrate via 420 is formed from the second surface of the first substrate 100 opposing the first surface.

On the other hand, a second via 422 is formed in a second substrate 102 from the side of the first substrate 100 in the same manner as in the fourth embodiment.

The first substrate via 420 and the second via 422 are disposed so as to be connected with each other. That is, the first substrate via 420 and the second via 422 are disposed so as to overlap with each other in a plan view.

The other end of the first substrate via 420 is connected with one end of the second via 422 by way of a bump 720.

Other constitution and the manufacturing method are identical with those of the fourth embodiment.

According to the eighth embodiment, effects identical with those of the fourth embodiment can be obtained.

### Ninth Embodiment

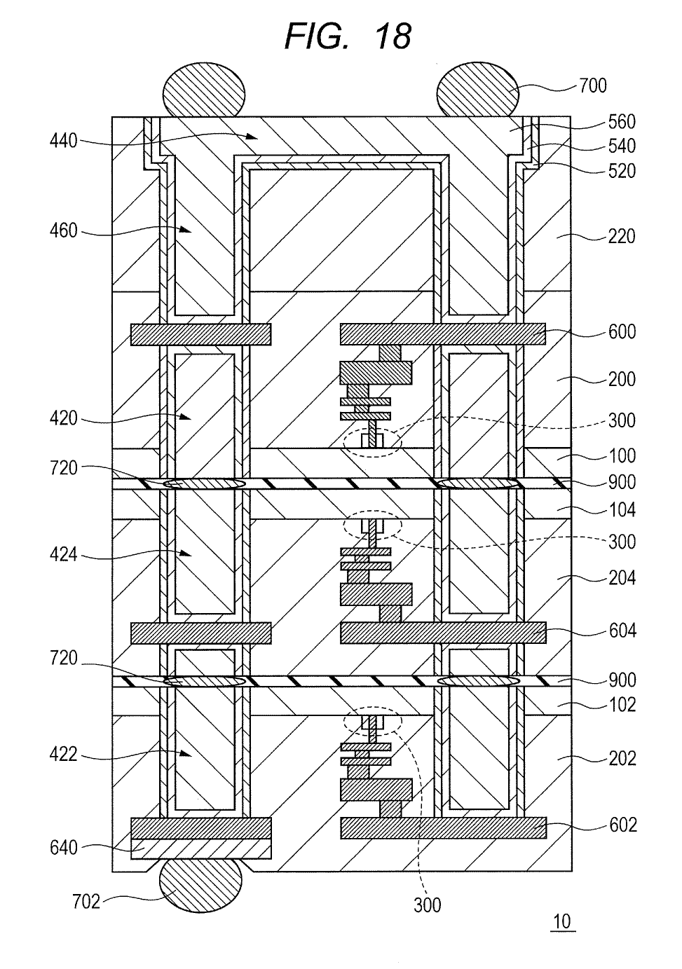

FIG. 18 is a cross sectional view showing the configuration of a semiconductor device 10 according to a ninth embodiment. The ninth embodiment is identical with the fifth embodiment except that a first substrate 100 is identical with that of the seventh embodiment. This embodiment is to be described specifically.

As shown in FIG. 18, this embodiment has at least one third substrate 104 provided between the first substrate 100 and a second substrate 102. The third substrate 104 is joined at each of the joining surfaces with each of the first substrate 100 and the second substrate 102 by way of a joining layer 900. The third substrate 104 may be disposed by one or in plurality.

In the same manner as in the seventh embodiment, a first substrate via 420 is formed from the second surface of the first substrate 100 opposing the first surface.

On the other hand, a third via 424 is formed from the third substrate 104 on the side of the first substrate 100 in the same manner as in the fifth embodiment. Further, a second via 422 is formed from the second substrate 102 on the side of the first substrate 100 in the same manner as in the fourth embodiment.

The first substrate via 420 and the third via 424 are disposed so as to be connected with each other. That is, the first substrate via 420 and the third via 424 are disposed so as to overlap in a plan view.

One end of the third via 424 or the fourth interconnect 604 is respectively connected by way of a bump 720 to the other end of the first substrate via 420 or one end of the second via 422.

As described above, when the third substrate 104 is joined, it is not restricted to the configuration shown in FIG. 18 but may be in a configuration which is turned upside down. Further, also when a plurality of the third substrates 104 are joined, the respective third substrates 104 can be joined with optional joining surfaces.

Further, as another modified embodiment, the second substrate 102 may be joined such that the third interconnect 602 is disposed to the first surface on the side of the first substrate 100.

According to the ninth embodiment, the effect identical with that of the fifth embodiment can be obtained.

For the third and seventh embodiments, while the description has been made to a case where the second bump electrode 702 is not formed, the second via 422 or the first interconnect 440 may be formed in the second substrate 102 from the side of the substrate surface as in the first embodiment. In this case, one end of the second via 422 may also be connected with the third interconnect 602. Further, the second bump electrode 702 may also be disposed just above the second via 422 or the first interconnect 440.

While the present invention has been described for the preferred embodiments with reference to the drawings, they are examples of the present invention and various other configurations than those described above may also be adopted.

1. A semiconductor device comprising:
a first substrate;
a first via penetrating the first substrate from a first surface of the first substrate; and
a first interconnect buried in the first surface of the first substrate and connected with one end of at least one first via,
wherein the first via has an inclined portion where an angle formed between the lateral side of the first via and the bottom of the first via is larger than an angle formed between the lateral side of the first interconnect and the bottom of the first interconnect.

2. The semiconductor device according to claim 1,
wherein the first substrate has a second interconnect disposed over a second surface opposing the first surface, and
wherein the other end of the first via is connected with the second interconnect.

3. The semiconductor device according to claim 2,
wherein the first substrate has a first interlayer insulating film disposed over the second surface,
wherein the second interconnect is buried in the first interlayer insulating film,
wherein the first via penetrates the first substrate and also penetrates the first interlayer insulating film, and
wherein the other end of the first via is connected with the second interconnect.

4. The semiconductor device according to claim 2,
wherein the second interconnect is a power supply interconnect or a ground interconnect.

5. The semiconductor device according to claim 2,
wherein the first substrate has a first bump electrode connected with the second interconnect over the second surface opposing the first surface.

6. The semiconductor device according to claim 2, further comprising:
a third interconnect disposed over the first surface of the first substrate and a second substrate joined to the first substrate on the side of the second surface opposing the first surface,
wherein the second interconnect is connected by way of a bump with the third interconnect.

7. The semiconductor device according to claim 2, further comprising:
a second substrate joined to the first substrate on the side of the second surface opposing the first surface, and
at least one third substrate joined between the first substrate and the second substrate,
wherein the second substrate includes a third interconnect disposed to the first surface on the side of the first substrate,
wherein the third substrate includes:
a third via penetrating the third substrate from the first surface of the third substrate and forming at one end a surface identical with the first surface of the third substrate, and
a fourth interconnect disposed over the second surface of the third substrate opposing the first surface of the third substrate and connected with the other end of the third via, and
wherein the one end of the third via or the fourth interconnect is connected respectively by way of a bump to the second interconnect of the first substrate or the third interconnect of the second substrate.

8. The semiconductor device according to claim 2, further comprising:
a second substrate joined to the first substrate on the side of the second surface opposing the first surface,
wherein the second substrate includes:
a second via penetrating the second substrate from the first surface on the side of the first substrate and forming at one end a surface identical with the first surface on the side of the first substrate, and
a third interconnect disposed on the side opposing the first substrate and connected with the other end of the second via, and
wherein the second interconnect is connected by way of a bump to the one end of the second via.

9. The semiconductor device according to claim 2, further comprising:
a second substrate joined to the first substrate on the side of the second surface opposing the first surface, and
at least one third substrate joined between the first substrate and the second substrate,
wherein the second substrate includes:
a second via penetrating the second substrate from the first surface on the side of the first substrate and forming at one end a surface identical with the first surface on the side of the first substrate, and
a third interconnect disposed on the side opposing the first substrate and connected with the other end of the second via,
wherein the third substrate includes:
a third via penetrating the third substrate from the first surface of the third substrate and forming at one end a surface identical with the first surface of the third substrate, and
a fourth interconnect disposed to the third substrate over the second surface opposing the first surface and connected with the other end of the third via, and
wherein the one end of the third via or the fourth interconnect is connected respectively by way of a bump to the second interconnect of the first substrate or the one end of the second via of the second substrate.

10. A semiconductor device comprising:
a first substrate;
a first interlayer insulating film disposed over a first surface of the first substrate;
a first interlayer via penetrating the first interlayer insulating film; and
a first interconnect buried in a surface of the first interlayer insulating film and connected with one end of at least one first interlayer via,
wherein the first interlayer via has an inclined portion where an angle formed between the lateral side of the first interlayer via and the bottom of the first interlayer via is larger than an angle formed between the lateral side of the first interconnect and the bottom of the first interconnect.

11. The semiconductor device according to claim 10, further comprising:
a second interconnect buried in the first interlayer insulating film and connected with the other end of the first interlayer via.

12. The semiconductor device according to claim 11, further comprising:
a first substrate via penetrating the first substrate from a second surface opposing the first surface and connected at the one end with the second interconnect and forming at the other end a surface identical with the second surface.

13. The semiconductor device according to claim 12, further comprising:
a second substrate having a third interconnect disposed over the first surface on the side of the first substrate and joined to the first substrate on the side of the second surface opposing the first surface,
wherein the other end of the first substrate via is connected by way of a bump with the third interconnect.

14. The semiconductor device according to claim 12, further comprising:
a second substrate joined to the first substrate on the side of the second surface opposing the first surface; and
at least one third substrate between the first substrate and the second substrate,
wherein the second substrate includes a third interconnect disposed over the first surface on the side of the first substrate,
wherein the third substrate includes:
a third via penetrating the third substrate from the first surface of the third substrate and forming at one end a surface identical with the first surface of the third substrate; and
a fourth interconnect disposed over the second surface of the third substrate opposing the first surface of the third substrate and connected with the other end of the third via, and
wherein the one end of the third via or the fourth interconnect is connected respectively by way of a bump to the other end of the first substrate via or the third interconnect of the second substrate.

15. The semiconductor device according to claim 12, further comprising:
a second substrate joined to the first substrate on the side of the second surface opposing the first surface,
wherein the second substrate includes:
a second via penetrating the second substrate from the first surface on the side of the first substrate and forming at one end a surface identical with the first surface on the side of the first substrate, and
wherein a third interconnect disposed on the side opposing the first substrate and connected with the other end of the second via, and
wherein the other end of the first substrate via is connected by way of a bump with the one end of the second via.

16. The semiconductor device according to claim 12, further comprising:
a second substrate joined to the first substrate on the side of the second surface opposing the first surface; and
at least one third substrate between the first substrate and the second substrate,
wherein the second substrate includes:
a second via penetrating the second substrate from the first surface on the side of the first substrate and forming at one end a surface identical with the first surface on the side of the first substrate; and
a third interconnect disposed on the side opposing the first substrate and connected with the other end of the second via,
wherein the third substrate includes:
a third via penetrating the third substrate from the first surface of the third substrate and forming at one end a surface identical with the first surface; and
a fourth interconnect disposed over the second surface opposing the first surface and connected with the other end of the third via, and
wherein the one end of the third via or the fourth interconnect is connected respectively by way of a bump to the other end of the first substrate via or the one end of the second via of the second substrate.

17. The semiconductor device according to claim 6,
wherein the third interconnect is a power supply interconnect or a ground interconnect.

18. The semiconductor device according claim 6,
wherein the first substrate includes a logic circuit, and
wherein the second substrate comprises a memory device for storing signals transmitted from the logic circuit.

19. The semiconductor device according to claim 7,
wherein the first substrate comprises a logic circuit, and
wherein the second substrate or the third substrate includes a memory device for storing signals transmitted from the logic circuit.

20. The semiconductor device according to claim 8,
wherein the second substrate includes a second bump electrode disposed over the surface on the side opposing the first substrate and connected with the third interconnect.

21. The semiconductor device according to claim 1,
wherein the first substrate further includes a first bump electrode connected with the via or the first interconnect over the first surface.

22. The semiconductor device according to claim 1, wherein the inclined portion has:
an angle formed between the lateral side of the via and the bottom of the via of 97 degrees or more and 105 degrees or less, and
an angle formed between the lateral side of the first interconnect and the bottom of the first interconnect of 90 degrees or more and 95 degrees or less.

23. The semiconductor device according to claim 1,
wherein a liner insulating film is provided on the lateral side inside the via, and
wherein the film thickness assumed as a (nm) at one end of the via and the film thickness assumed as b (nm) at the other end of the via are in a relation: b−a≧7.

24. A method of manufacturing a semiconductor device comprising:
an etching step of forming a first via hole penetrating a first substrate from a first surface of the first substrate and forming a first interconnect trench connected with one end of at least one first via hole; and
a metal burying step of burying a metal in the first via hole and the first interconnect trench, thereby forming a first via and a first interconnect,
wherein an inclined portion is formed in the first via hole where an angle formed between the lateral side and the bottom is larger than an angle formed between the lateral side of the first interconnect trench and the bottom of the first interconnect trench in the etching step.

25. The method of manufacturing a semiconductor device according to claim 24, further comprising:
a step of forming a second interconnect in the first substrate on the side of the second surface opposing the first surface before the etching step,
wherein the other end of the first is connected via hole with the second interconnect in the etching step.

26. The method of manufacturing a semiconductor device according to claim 25, further comprising:
a step of preparing a second substrate having a third interconnect to the first surface on the side of the first substrate; and
a joining step of joining the second substrate to the first substrate on the side of the second surface opposing the first surface,
wherein the second interconnect is connected by way of a bump with the third interconnect in the joining step.

27. The method of manufacturing a semiconductor device according to claim 25, further comprising:
a step of preparing a second substrate and at least one third substrate; and
a joining step of joining the third substrate and the second substrate successively to the first substrate on the side of the second surface opposing the first surface,
wherein the second substrate has a third interconnect disposed over the first surface on the side of the first substrate,
wherein the third substrate includes:
a third via penetrating the third substrate from the first surface of the third substrate and forming at one end a surface identical with the first surface of the third substrate; and
a fourth interconnect disposed to the third substrate over the second surface opposing the first surface and connected with the other end of the third via, and
wherein the one end of the third via or the fourth interconnect is connected respectively by way of a bump with the second interconnect of the first substrate or the third interconnect of the second substrate in the joining step.

28. The method of manufacturing a semiconductor device according to claim 25, further comprising:
a step of preparing a second substrate; and
a joining step of joining the second substrate to the first substrate on the side of the second surface opposing the first surface
wherein the second substrate includes:
a second via penetrating the second substrate from the first surface on the side of the first substrate and forming at one end a surface identical with the first surface on the side of the first substrate; and
a third interconnect disposed on the side opposing the first substrate and connected with the other end of the second via, and
wherein the second interconnect is connected by way of a bump to one end of the second via in the joining step.

29. The method of manufacturing a semiconductor device according to claim 25, further comprising:
a step of preparing a second substrate and at least one third substrate; and
a joining step of joining the third substrate and the second substrate successively to the first substrate on the side of the second surface opposing the first surface,
wherein the second substrate includes:
a second via penetrating the second substrate from the first surface on the side of the first substrate and forming at one end a surface identical with the first surface on the side of the first substrate; and
a third interconnect disposed on the side opposing the first substrate and connected with the other end of the second via,
wherein the third substrate includes:
a third via penetrating the third substrate from the first surface of the third substrate and forming at one end a surface identical with the first surface of the third substrate; and
a fourth interconnect disposed to the third substrate over the second surface opposing the first substrate and connected with the other end of the third via, and
wherein the one end of the third via or the fourth interconnect is connected respectively by way of a bump with the second interconnect of the first substrate or the one end of the second via of the second substrate.

30. A method of manufacturing a semiconductor device comprising:
a step of forming a first interlayer insulating film over the first surface of a first substrate;
an etching step of forming an interlayer via hole penetrating the first interlayer insulating film and forming a first interconnect trench connected with one end of at least one first interlayer via hole; and
a metal burying step of burying a metal in the first interlayer via hole and the first interconnect trench, thereby forming a first interlayer via and a first interconnect,
wherein an inclined portion is formed in the first interlayer via hole where an angle formed between the lateral side and the bottom of the first interlayer via hole is larger than an angle formed between the lateral side of the first interconnect trench and the bottom of the first interconnect trench in the etching step.

31. The method of manufacturing a semiconductor device according to claim 30,
wherein a second interconnect is formed in the first interlayer insulating film in the step of forming the first interlayer insulating film, and
wherein the other end of the first interlayer via hole is connected with the second interconnect in the etching step.

32. The method of manufacturing a semiconductor device according to claim 31, further comprising:
a step of forming a first substrate via such that the first via penetrates the first substrate from the second surface opposing the first surface, is connected at one end with the second interconnect, and forms a surface identical with the second surface at the other end on the side of the second surface.

33. The method of manufacturing a semiconductor device according to claim 32, further comprising:
a step of preparing a second substrate having a third interconnect over the first surface on the side of the first substrate; and
a joining step of joining the second substrate to the first substrate on the side of the second surface opposing the first surface,
wherein the other end of the first substrate is connected via by way of a bump with the third interconnect in the joining step.

34. The method of manufacturing a semiconductor device according to claim 32, further comprising:
a step of preparing a second substrate and at least one third substrate; and
a joining step of joining the third substrate and the second substrate successively to the first substrate on the side of the second surface opposing the first surface,
wherein the second substrate has a third interconnect disposed over the surface on the side of the first substrate,
wherein the third substrate includes:
a third via penetrating the third substrate from the first surface of the third substrate and forming at one end a surface identical with the first surface of the third substrate; and
a fourth interconnect disposed to the third substrate over the second surface opposing the first surface and connected with the other end of the third via, and
wherein the one end of the third via or the fourth interconnect is connected respectively by way of a bump with the other end of the first substrate via or the third interconnect of the second substrate in the joining step.

35. The method of manufacturing a semiconductor device according to claim 32, further comprising:
a step of preparing a second substrate; and
a joining step of joining the second substrate to the first substrate on the side of the second surface opposing the first surface,
wherein the second substrate includes:
a second via penetrating the second substrate from the first surface on the side of the first substrate and forming at one end a surface identical with the first surface of the side of the first substrate; and
a third interconnect disposed on the side opposing the first substrate and connected with the other end of the second via, and
wherein the other end of the first substrate via is connected by way of a bump with the other end of the second via in the joining step.

36. The method of manufacturing a semiconductor device according to claim 32, further comprising:
a step of preparing a second substrate and at least one third substrate; and
a joining step of joining the third substrate and the second substrate successively to the first substrate on the side of the second surface opposing the first surface,
wherein the second substrate includes:
a second via penetrating the second substrate from the first surface on the side of the first substrate and forming at one end a surface identical with the first surface on the side of the first substrate; and
a third interconnect disposed on the side opposing the first substrate and connected with the other end of the second via,
wherein the third substrate includes:
a third via penetrating the third substrate from the first surface of the third substrate and forming at one end a surface identical with the first surface of the third substrate; and
a fourth interconnect disposed to the third substrate over the second surface opposing the first surface and connected with the other end of the third via, and
wherein the one end of the third via or the fourth interconnect is connected respectively by way of a bump with the other end of the first substrate via or the one end of the second via of the second substrate in the joining step.
